(19) United States
(12) Patent Application Publication
(10) Pub. No.: US 2026/0266867 A1
(43) Pub. Date: Sep. 10, 2026

(54) COMPUTER-IMPLEMENTED METHOD AND APPARATUS FOR PROCESSING A SAMPLE USING A NANOMANIPULATOR

(71) Applicant: Carl Zeiss SMT GmbH, Oberkochen (DE)

(72) Inventors: Christof Baur, Darmstadt (DE); Katharina Eberl, Frankfurt (DE); Rainer Fettig, Steinmauern (DE); Claudia Kroeckel, Egelsbach (DE); Hans Hermann Pieper, Schaafheim (DE); Dominik Schnoor, Dietzenbach (DE); Markus Waiblinger, Griesheim (DE); Julia Weber, Alsbach-Haehnlein (DE)

(21) Appl. No.: 19/657,658

(22) Filed: Apr. 24, 2026

Related U.S. Application Data
(63) Continuation of application No. PCT/EP2024/080401, filed on Oct. 28, 2024.

(30) Foreign Application Priority Data
Oct. 27, 2023 (DE) 102023129682.5

(51) Int. Cl. G01Q 10/06

(52) U.S. Cl. CPC G01Q 10/06

(57) ABSTRACT

The disclosure provides a method for landing a tip of a probe of a nanomanipulator on a sample, in particular in vacuum, the probe comprising a cantilever and the tip attached thereto, the nanomanipulator further comprising an excitation unit, the probe being mechanically coupled with the excitation unit, the method including the following steps:
oscillating the probe by providing a resonant driving signal to the excitation unit while the tip is not in contact with the sample;
reducing a first distance in a z-direction between the tip and the sample during a first approach phase until at least one first stop condition of a first set of stop conditions is met, wherein the first set of stop conditions comprises detecting a shift in the frequency of the resonant driving signal used during the first approach phase; and
terminating the first approach phase when the at least one first stop condition of the first set of stop conditions is met, and deactivating the resonant driving signal.

### CROSS-REFERENCE TO RELATED APPLICATIONS

This application is a continuation of and claims benefit under 35 U.S.C. § 120 from PCT Application No. PCT/EP2024/080401, filed on Oct. 28, 2024, which claims priority from German Application No. 10 2023 129 682.5, filed on Oct. 27, 2023. The entire contents of each of these earlier applications are incorporated herein by reference.

### TECHNICAL FIELD

The present invention relates to a computer-implemented method and an apparatus for processing a sample using a nanomanipulator.

### BACKGROUND

Microlithography is used for producing microstructured components, such as for example, integrated circuits. The microlithography process is carried out using a lithography apparatus comprising an illumination system and a projection system. The image of a mask (reticle) illuminated by use of the illumination system is projected here by use of the projection system onto a substrate, for example, a silicon wafer, which is coated with a light-sensitive layer (photoresist) and arranged in the image plane of the projection system, in order to transfer the mask structure to the light-sensitive coating of the substrate.

The mask (i.e., lithography mask) is used for a multiplicity of exposures, for which reason it is very important that the mask be free of defects and contaminations. Therefore, lithography masks are examined in regard to defects and contaminations at great expense. Attempts are then made to repair identified defects or to remove contaminations. The defects and contaminations may be extremely small and have sizes of the order of a few nanometers. Therefore, removing them requires apparatuses with very high spatial resolution.

The contaminations are, for example, extremely small particles which have deposited on the mask from the surroundings. Such contaminations occur to an increased extent, for example, if the mask is transferred between different processing apparatuses. The particles are of a very diverse nature and have different sizes and/or shapes. They may, for example, be metal particles, in particular tin, but ceramic particles, polymer particles and further carbon compounds may also occur. The particles are typically adsorbed on the mask surface, that is to say that there are no strong chemical bonds, such as atomic bonds, between the particle material and the mask surface.

A particle will leave the mask surface if applied attractive forces (e.g., Coulomb forces and van der Waals forces) for removing the particle are greater than attractive forces (e.g., Coulomb forces and van der Waals forces) of the mask surface. Depending on what kind of interaction there is between the particle and the mask surface, an activation energy may be necessary to break the existing bond to the mask surface.

### SUMMARY

Processing apparatuses are known which can remove individual particles from a surface in a targeted manner. For example, nanomanipulators, such as for example atomic force microscopes, are used for this purpose. In this case, a particle is picked up by a measuring tip (measuring and manipulator tip) of the nanomanipulator and, adhering to the measuring tip, is removed from the mask surface. Particle removal is usually supported by imaging methods (e.g., image recording by use of a scanning electron microscope and/or a scanning ion microscope) and requires manipulations by a user on nanometer scales. In this case, small errors on the part of a user may easily result in damage or destruction of the measuring tip of the nanomanipulator or of the sample. Moreover, the processing requires high attentiveness on the part of the user, as a result of which fatigue phenomena lead to an increased risk of errors on the part of the user.

Furthermore, processing the sample, in particular removing particles from the sample, is made more difficult by the fact that the precise position of the apex of the measuring tip is unknown. In particular, the apex of the measuring tip is the point and/or region of the measuring tip which makes initial contact with the sample or a particle on the sample when the measuring tip approaches the sample and/or particle. As a rule, the actual apex of the measuring tip cannot be seen in an image (e.g., a scanning electron microscope image and/or scanning ion microscope image) of the sample with the measuring tip, and so a lateral position of the apex cannot be derived from such an image on its own. Furthermore, a height position of the apex of the measuring tip (i.e., a distance from the sample) is generally not known accurately either on account of a deflection of a cantilever to which the measuring tip is secured.

Against this background, an aspect of the present invention is to improve the processing of a sample using a nanomanipulator.

Accordingly, a method for landing a tip of a probe of a nanomanipulator on a sample, in particular in vacuum, is proposed. The probe comprises a cantilever and the tip attached thereto. The nanomanipulator further comprises an excitation unit, the probe being mechanically coupled with the excitation unit. The method includes the following steps:
oscillating the probe by providing a resonant driving signal to the excitation unit while the tip is not in contact with the sample;
reducing a first distance in a z-direction between the tip and the sample during a first approach phase until at least one first stop condition of a first set of stop conditions is met, wherein the first set of stop conditions comprises detecting a shift in the frequency of the resonant driving signal used during the first approach phase; and/or
terminating the first approach phase when the at least one first stop condition of the first set of stop conditions is met, and deactivating the resonant driving signal.

This method may be used on its own or in combination with one or more of the other methods disclosed below.

Optionally, the method further comprises: further reducing the first distance during a second approach phase until at least one second stop condition of a second set of stop conditions is met, wherein the second set of stop conditions comprises detecting a deflection of the cantilever; and terminating the second approach phase at a contact position when the at least one second stop condition of the second set of stop conditions is met

Optionally, the location of at least one of the probe or the sample are controlled in the z-direction using a combination of a coarse drive and a fine drive.

Optionally, the method further comprising performing a third approach phase, comprising: increasing the first distance by operating the fine drive to move the tip from the contact position to a partially retracted position; and reducing or increasing the first distance by operating the coarse drive based on a second distance in the z-direction between the contact position and the partially retracted position; and reducing the first distance by operating the fine drive to return the tip to the contact position or to a predefined position at third distance in the z-direction from the contact position.

Optionally, the method further comprises determining at least one parameter of a resonance characteristic of the probe while the tip is not in contact with the sample, the at least one parameter comprising at least one of a resonance frequency of the probe, a Q-value of the probe, and a phase angle between the resonant driving signal and a detected deflection signal associated with the oscillation of the probe.

Optionally, the first set of stop conditions comprises at least one of the following conditions:
a frequency control signal (e.g., dF) indicative of shift in the frequency of the resonant driving signal exceeding a first threshold value;
a frequency control signal (e.g., dF) indicative of shift in the frequency of the resonant driving signal lying below a second threshold value;
an amplitude feedback signal (e.g., A) used for amplitude control of the resonant driving signal exceeding a third threshold value;
an amplitude feedback signal (e.g., A) used for amplitude control of the resonant driving signal lying below a fourth threshold value;
a phase signal indicative of a relationship between the resonant driving signal and a detected oscillation of the probe exceeding a fifth threshold value and/or lying below a sixth threshold value; and/or
a driving speed in the z-direction exceeding a seventh threshold value and/or lying below an eighth threshold value.

Optionally, landing the probe is aborted in the first approach phase when at least one of the following conditions are met: the frequency control signal lies below the second threshold value; the amplitude feedback signal exceeds the third threshold value; the phase signal exceeds the fifth threshold value and/or lies below the sixth threshold value; and/or the driving speed exceeds the seventh threshold value and/or lies below the eighth threshold value.

Optionally, the second set of stop conditions used in the second approach phase further comprises:
a first deflection signal (e.g., DFL) indicative of a deflection of the probe in the z-direction exceeding a first ninth threshold value;
a second deflection signal (e.g., LAT) indicative of a lateral deflection of the probe exceeding a tenth threshold value;
a sum signal (e.g., SUM) indicative of a combined deflection of the probe exceeding an eleventh threshold value; and/or
a driving speed in the z-direction exceeding a twelfth threshold value and/or lying below a thirteenth threshold value.

Optionally, landing the probe is aborted in the second approach phase when at least one of the following conditions are met: the driving speed exceeds the twelfth threshold value and/or lies below the thirteenth threshold value.

According to another embodiment, an apparatus is provided. The apparatus comprises: a sample stage for holding a sample; a nanomanipulator comprising a positioning unit and an excitation unit, the positioning unit being configured to move a probe comprising a cantilever and a tip attached thereto, the excitation unit being configured to oscillate the probe based on a driving signal; a cantilever deflection detection system configured for detecting deflections of the cantilever; a control loop circuitry configured to track a signal relationship between an oscillation of the cantilever detected by the cantilever detection system and a driving signal provided to the excitation unit; and at least one control unit. The at least one control unit is configured to perform the following steps: driving, using the excitation unit, the probe using a resonant driving signal provided by the control loop circuitry while the tip is not in contact with the sample; reducing, by the positioning unit, a first distance in a z-direction between the tip and the sample during a first approach phase until at least one first stop condition of a first set of stop conditions is met, wherein the first set of stop conditions comprises detecting a shift in the frequency of the resonant driving signal used during the first approach phase; and terminating the first approach phase when the at least one first stop condition of the first set of stop conditions is met by deactivating the resonant driving signal.

Optionally, the control loop circuitry comprises: a frequency control system configured to provide a first output signal based on a phase of a detected oscillation of the cantilever and a phase setpoint; and an amplitude control system configured to provide a second output signal based on an amplitude of the detected oscillation of the cantilever and an amplitude setpoint; and a multiplier configured to multiply the first output signal provided by the frequency control system with the second output signal provided by the amplitude control system and to provide the multiplied signal as resonant driving signal to the excitation unit.

Optionally, the frequency control system comprises a phase detector for providing a phase signal, an integrator for providing a frequency control signal, and a controllable oscillator for providing an oscillator output signal.

Optionally, the amplitude control system comprises an amplitude detector for providing an amplitude signal, and a PI controller for providing an amplitude feedback signal.

According to another aspect, a computer-implemented method for processing a sample using a nanomanipulator is proposed. The nanomanipulator comprises a measuring tip for processing the sample and a positioning unit for moving the measuring tip. Furthermore, the sample is arranged on a sample stage. An x-direction and a y-direction of the nanomanipulator are each arranged parallel to a main extension plane of the sample and/or sample stage and perpendicular to one another. The method comprises the following steps:
1a) controlling the positioning unit to move the measuring tip in the y-direction such that an apex of the measuring tip is in contact with a surface of a test region of the sample stage or sample, and the measuring tip leaves a first track on the surface,
1b) controlling the positioning unit to move the measuring tip in the x-direction such that the apex of the measuring tip is in contact with the surface, and the measuring tip leaves a second track on the surface,
1c) controlling an image recording device to record at least one image of the test region in each case, the first and the second track being at least partially captured accordingly therein, and
1d) ascertaining an x-position of the apex of the measuring tip in relation to the x-direction on the basis of the first track captured in the at least one image and ascertaining a y-position of the apex of the measuring tip in relation to the y-direction on the basis of the second track captured in the at least one image.

Using the method, it is possible to ascertain the x- and y-position of the actual apex of the measuring tip, even if only the apparent apex of the measuring tip is visible in the captured and received image. In particular, the actual apex of the measuring tip might not be visible in the image because it is concealed in relation to a line-of-sight of the image recording device.

In particular, the apex of the measuring tip is the point and/or region of the measuring tip which makes initial contact with the sample or a particle on the sample when the measuring tip approaches the sample and/or particle. For example, the apex of the measuring tip is a lowest point and/or region of the measuring tip in relation to a z-direction of the nanomanipulator. In particular, the measuring tip of the nanomanipulator is configured to contact a surface of the sample at its apex. In particular, the z-direction of the nanomanipulator is arranged perpendicular to the x- and the y-direction. In particular, the z-direction of the nanomanipulator corresponds to a vertical direction of the nanomanipulator or its direction of gravity.

In particular, the x- and y-directions of the nanomanipulator are any desired directions which are each arranged parallel to the main extension plane of the sample and/or sample stage (e.g., a surface of the sample stage for arrangement of the sample) and perpendicular to one another.

For example, the x-, y- and z-directions of the nanomanipulator can correspond to x-, y- and z-directions of the positioning unit of the nanomanipulator.

For example, the sample is a lithography mask with structures (e.g., absorber structures). The structures have, for example, a structure size in the range of 10 nm-10 μm. The structures are arranged, for example, in a structure pattern for producing a specific type of semiconductor chip. The sample can be, for example, a transmissive lithography mask for DUV lithography (DUV: “deep ultraviolet”, operating light wavelengths in the range of 30-250 nm) or a reflective lithography mask for EUV lithography (EUV: “extreme ultraviolet”, operating light wavelengths in the range of 1-30 nm, in particular 13.5 nm).

The sample can also be a microelectronic component, such as for example an integrated circuit, in particular a CPU (CPU: “central processing unit”), GPU (GPU: “graphics processing unit”), a RAM memory (RAM: “random access memory”), a flash memory and suchlike.

The nanomanipulator and/or a superordinate apparatus comprising the nanomanipulator comprise(s), for example, a sample stage device having a mount, a sample stage for arrangement of the sample and movably arranged on the mount, and a further positioning unit for moving the sample stage relative to the mount. The sample stage can be moved, for example, with the aid of the further positioning unit in the x-direction and the y-direction (i.e., laterally) and/or in the z-direction (vertical direction or direction of gravity). The sample stage can, for example, also be mounted rotatably on the mount, such that it can be rotated about the x-, y- and/or z-direction with the aid of the further positioning unit. The sample stage comprises in particular a surface for arrangement of the sample.

The measuring tip is in particular a tip configured for measurement and manipulation (measuring and manipulator tip).

The nanomanipulator comprises a cantilever, for example, on which the measuring tip is arranged and/or secured. The cantilever and the measuring tip can also have a monolithic design. The term cantilever also appears in the German text as “Cantilever”. The measuring tip has, for example, a length in the range of 0.5 μm-1 mm and a diameter in the range of 20 nm-1 μm. In particular, the measuring tip can taper towards its free end.

For example, the measuring tip consists of a material including carbon, silicon, one or more noble metals, tungsten, platinum, iridium and/or a platinum-iridium alloy. The measuring tip makes it possible to move to individual positions on the sample surface in a targeted manner, in particular even if the sample has structures having a high aspect ratio. The aspect ratio may be defined, for example, as the ratio of width to height of a structure. An example of a structure having a high aspect ratio of 1:10 is a narrow, deep trench which, for example, is 1 μm wide and 10 μm deep.

For example, when expressed as a Mohs harness, the measuring tip has a hardness of 7 or more, 8 or more and/or 9 or more. The Mohs hardness is a hardness based on the Mohs scale developed by Friedrich Mohs.

The nanomanipulator comprises the positioning unit, on which the cantilever is mounted movably and which enables the cantilever to be moved in the three spatial directions x, y and z relative to the positioning unit (translational movement in the three spatial directions). The three spatial directions span in particular a three-dimensional space. The positioning unit is secured, for example, to a housing of the nanomanipulator and/or a superordinate apparatus comprising the nanomanipulator.

The cantilever has in particular an elongate shape with a longitudinal axis. Furthermore, the cantilever is secured to the positioning unit movably at a first end in relation to its longitudinal axis. With the aid of the positioning unit, a position of the first end of the cantilever (also called base point or base end of the cantilever) can thus be set in the three spatial directions x, y and z. Moreover, the cantilever has the measuring tip at a second end (free end) in relation to its longitudinal axis.

If the measuring tip comes into the vicinity of the sample surface, an interaction occurs between the measuring tip and the sample surface. The interaction may be based on direct contact, on a van der Waals interaction or further physical interactions, and mixtures thereof. By way of the measuring tip being moved (raster-scanned) over the sample surface, a three-dimensional image of the sample surface can be captured. In this case, for example, for each raster-scan position the distance between the measuring tip and the sample surface is kept constant by use of a closed-loop control circuit and a position of a microactuator for setting the distance is captured.

In particular, the particle is a foreign body, such as dust or dirt, which has deposited on the sample surface. It may also be said that the particle is adsorbed on the sample surface. Particles absorbed on the sample surface may have different constitutions and different shapes. For example, the size of the particles ranges from 3 nm-50 μm.

Such a particle can, for example, be located on the sample surface by use of optical analysis methods and approached by the measuring tip in a targeted manner. In order to pick up the particle with the measuring tip, the particle must be detached from the sample surface. That means that the forces acting between the sample surface and the particle must be overcome. The strength with which the particle is bound to the sample surface depends both on the shape and constitution of the particle and on the constitution of the sample surface, in particular the surface energy thereof. The greater the surface energy of the surface, the more strongly the particle is adsorbed.

To pick up the particle with the measuring tip, the measuring tip is, for example, brought into contact with the particle. If attractive forces of the measuring tip are greater than attractive forces of the sample surface, the particle will be able to be detached from the sample surface and can be picked up by the measuring tip.

It may be helpful to first use the measuring tip to displace the particle on the sample surface in order to break existing bonds between particle and sample surface. It is thereby possible, for example, to reduce the binding energy of the particle in relation to binding to the surface. Furthermore, for example, a contact area between the measuring tip and the particle can be increased as a result. If the contact area between the particle and the measuring tip becomes larger, the probability that the particle will adhere to the measuring tip and be able to be detached from the sample surface increases.

After the particle has been picked up by the measuring tip, the particle must be removed again from the measuring tip in order to be able to continue to use the measuring tip. The particle should in this case in particular be deposited at a position on the sample surface at which it is not a disturbance, or on a separate deposition unit.

The nanomanipulator can be part of a superordinate apparatus for processing the sample, the apparatus comprising the nanomanipulator.

The superordinate apparatus for processing the sample can, for example, also comprise a control apparatus for performing the proposed method. For example, the control apparatus controls the positioning unit in step 1a) to move the measuring tip in the y-direction in order to write the first track in the y-direction. For example, the control apparatus controls the positioning unit in step 1b) to move the measuring tip in the x-direction in order to write the second track in the x-direction. For example, the control apparatus controls the image recording device in step 1c) to record at least one image of the test region in each case. For example, the control apparatus receives the recorded images from the image recording device. For example, the control apparatus accordingly ascertains in step 1d) the x-position and the y-position of the apex of the measuring tip on the basis of the first and the second track captured in the images.

Moreover, the superordinate apparatus for processing the sample can, for example, also comprise an image recording device, e.g., a scanning electron microscope and/or a scanning ion microscope, for recording images of the sample.

In particular, the test region of the sample stage or sample, into the material of which the first and the second track are written, is a region of the sample stage or sample in which the tracks are not bothersome. For example, a test region of the sample is a region that is not required when the sample is used (e.g., as a mask in lithography).

For example, the sample comprises a substrate, a capping layer and/or structures (e.g., absorber structures) made of a material with a first hardness. Furthermore, the test region of the sample stage or sample, for example, comprises a material with a second hardness, which is less than the first hardness. The first and second hardness each denote a mechanical resistance which the respective material exhibits against mechanical penetration by the apex of the measuring tip.

For example, the first and the second track are each tracks, for example, engraved tracks and/or scratched tracks, written into a material of the test region by the apex of the measuring tip. For example, the first and the second tracks each have depressions relative to a surface of the test region before the first and the second track are applied. The first track is arranged parallel to the y-direction in particular, and the second track is arranged parallel to the x-direction in particular.

Following step 1a) in particular, steps 1c) and 1d) are initially carried out for the first track only. In this case, the image recording device is controlled in step 1c) to record at least one image of the test region, the first track being at least partially captured therein. Following step 1b), steps 1c) and 1d) are carried out again, only for the second track in this case. In this case, the image recording device is controlled in step 1c) to record at least one image of the test region, the second track being at least partially captured therein.

For example, in a first arrangement variant, the first and the second track can be created on the surface of the test region, in such a way that the first and the second track are arranged on the surface at a distance from one another and without contact with one another. In other words, the first and the second track are not contiguous in this case.

For example, in a second arrangement variant, the first and the second track can also be created on the surface of the test region, in such a way that the first and the second track intersect (e.g., intersect at right angles).

For example, in a third arrangement variant, the first and the second track—in addition to the two tracks intersecting or instead of the two tracks intersecting—can be portions of a contiguous overall track.

Moreover, the apex of the measuring tip can, for example, be removed from the surface of the test region between the creation of the first track and the creation of the second track in one, more and/or all of the three aforementioned arrangement variants.

For example, the image recording device is a scanning electron microscope and/or a scanning ion microscope. Furthermore, the x-position and the y-position of the apex of the measuring tip is ascertained in this case on the basis of at least one scanning electron microscope image or scanning ion microscope image received from the scanning electron microscope or scanning ion microscope.

According to an embodiment, the nanomanipulator comprises a cantilever having a base end and a free end, wherein the measuring tip is arranged at the free end of the cantilever, and, at its base end, the cantilever is secured to the positioning unit so as to be movable. Moreover, the positioning unit is controlled to move the base end of the cantilever such that the measuring tip is moved.

For example, the positioning unit is controlled by the control apparatus. In particular, the positioning unit is controlled to move the base end of the cantilever such that the measuring tip is moved as well.

According to a further embodiment, the x-position and the y-position of the apex of the measuring tip are ascertained by accordingly fitting a respective straight line to the first and the second track captured in the image.

Fitting the respective straight line is performed by the control apparatus, for example. For example, the respective straight line is fitted by a computer-assisted approximation method, in which a respective linear function is fitted to the first track captured in the image or to the second track captured in the image.

According to a further embodiment, the measuring tip is at least partially captured in the at least one image, wherein a lateral position of an apparent apex of the measuring tip in the at least one image deviates from a lateral position of an actual apex of the measuring tip in the at least one image, and the lateral position of the actual apex of the measuring tip is ascertained relative to the lateral position of the apparent apex of the measuring tip in the at least one image.

An offset between the x- and y-position of the actual apex of the measuring tip (not visible in the image) and the x- and y-position of the apparent apex of the measuring tip (visible in the image) can be ascertained with knowledge of the lateral position (i.e., the x- and y-position) of the actual apex of the measuring tip relative to the lateral position (i.e., the x- and y-position) of the apparent apex of the measuring tip in the at least one image. Since this x- and y-offset generally does not change for a specific measuring tip, the x- and y-position of the actual apex of the measuring tip can easily be ascertained with the aid of the ascertained x- and y-offset based on any desired image of the measuring tip, recorded in particular along the same line-of-sight.

Accurate knowledge of the x- and y-position of the actual apex of the measuring tip used to process a sample enables more accurate processing of the sample. For example, a particle on the sample can be removed in more targeted fashion and better with the aid of the measuring tip as a result.

In particular, the image is a two-dimensional image.

According to a further embodiment, the lateral position of the actual apex of the measuring tip is ascertained relative to a lateral position of the base end of the cantilever.

As a result, the contact point between the actual apex of the measuring tip and the surface of the sample can be ascertained at any time when the measuring tip is visible in the image.

According to another aspect, a method for landing a probe or processing a sample comprises: capturing a first image of a surface of the sample, the first image comprising a least one section not obscured by the tip; generating a second image, the second image comprising as least one section obscured by the tip and at least one mark arranged in the obscured section, indicating a position of at least one hidden element; and displaying the second image on a user interface to an operator of the nanomanipulator during manipulation of the sample. This method may be used on its own or in combination with one or more of the other methods disclosed above or below.

Optionally, the at least one mark comprises at least one of the following: a contact point indicator indicating a position of a contact point of the tip with the sample; a structure indicator indicating an edge or an area of a surface feature or a particle located on the surface of the sample; and a tip indicator indicating an outline of the tip, wherein the tip is replaced in the second image by a corresponding section of the surface of the sample obtained from the first image.

According to a further embodiment, the nanomanipulator comprises a deflection detection device for detecting a z-deflection of the free end of the cantilever in a z-direction which is arranged perpendicular to the x- and the y-direction and which points away from the sample. In addition, the method includes:
6a) controlling the positioning unit to move the base end of the cantilever in the negative z-direction such that a z-distance in relation to the z-direction is reduced between the base end of the cantilever and the sample, and the measuring tip is made to approach the sample in a test region of the sample,
6b) repeatedly receiving, from the deflection detection device, an extent of the z-deflection of the free end of the cantilever depending on the z-distance of the base end of the cantilever from the sample,
6c) ascertaining an approach curve which contains the extent of the z-deflection of the free end of the cantilever as a function of the z-distance of the base end of the cantilever from the sample,
6d) receiving at least one image of the sample, the test region being at least partially captured therein,
6e) ascertaining whether the sample is damaged in the test region using the at least one received image as a basis, and
6f) storing a minimal z-deflection and/or a minimal z-distance of the approach curve as a safe z-deflection of the free end of the cantilever or as a safe z-distance of the base end of the cantilever from the sample should the sample be ascertained as being undamaged in the test region.

As a result, it is possible to ascertain a safe deflection of the free end of the cantilever and hence a safe minimal distance of the apex of the measuring tip from the sample in the z-direction even though the precise z-position of the apex of the measuring tip is generally unknown.

In this case, the nanomanipulator is used as a force sensor in particular, and force distance spectroscopy is performed.

For example, the x-, y- and z-position of the base end of the cantilever is known accurately relative to the positioning unit. In particular, the x-, y- and z-position of the base end of the cantilever can be set by controlling the positioning unit. Consequently, current values of the x-, y- and z-position of the base end of the cantilever relative to the positioning unit can be provided by the positioning unit, for example. In particular, the z-position of the base end of the cantilever can thus be provided by the positioning unit, and hence it is known accurately. Nevertheless, the precise z-position of the apex of the measuring tip might be unknown on account of the changing deflection of the free end of the cantilever and on account of a possible bending of the measuring tip relative to the cantilever.

The deflection of the free end of the cantilever in the z-direction is caused by forces that act between the measuring tip and the sample. The deflection of the free end of the cantilever in the z-direction is moreover proportional to a spring constant of the cantilever. In particular, the cantilever bends to different extents during the scanning of the sample according to the forces acting between measuring tip and sample. An extent of this bending or deflection of the free end of the cantilever in the z-direction can be detected with the aid of the deflection detection device. The nanomanipulator and/or a superordinate apparatus comprising the nanomanipulator comprise(s) such a deflection detection device, for example.

For example, the deflection detection device is a light pointer device. The light pointer device comprises, for example, a laser source and a position-sensitive photodetector. A laser beam emitted by the laser source is directed at the free end of the cantilever and reflected from there in an undeflected position of the cantilever into the center of the position-sensitive photodetector. The photodetector is subdivided for example into four regions: “top left”, “top right”, “bottom left” and “bottom right”. If the bending (deflection) of the cantilever changes, then the reflected laser spot shifts on the photodetector as in the case of the light pointer. By measuring the intensities in the four regions of the photodetector, it is possible to determine vertical and horizontal bending signals which are proportional to the normal force and respectively to lateral forces.

Moreover, bending (i.e., an elastic deformation) of the measuring tip relative to the cantilever can occur as a result of interaction of the measuring tip with the sample (e.g., as a result of a lateral movement of the measuring tip upon contact between the measuring tip and the sample). An extent of this bending of the measuring tip relative to the cantilever can be ascertained by means of image processing in recorded images (e.g., scanning electron microscope images, scanning ion microscope images) of the measuring tip.

For example, the x- and y-position of the base end of the cantilever is kept constant in step 6a).

In particular, the test region of the sample is a region in which damage to the sample is not bothersome. For example, the test region of the sample is a region that is not required when the sample is used (e.g., as a mask in lithography).

For example, damage to the test region includes dented material in the test region.

For example, the safe deflection is stored in a storage device of the nanomanipulator.

For example, before controlling the positioning unit to move the measuring tip in the negative z-direction, the method includes:
controlling the positioning unit to move the measuring tip laterally (i.e., in the x- and/or y-direction) into the test region of the sample,
wherein the x- and the y-position of the base end of the cantilever are kept constant during the subsequent controlling of the positioning unit to move the measuring tip in the negative z-direction.

For example, after ascertaining the approach curve, the method includes controlling the positioning unit to move the measuring tip in the positive z-direction by a predetermined z-distance (withdrawing the measuring tip from the sample by the predetermined z-distance).

For example, steps 6a) to 6f) are carried out by the control apparatus.

In embodiments, the positioning unit is controlled in step 6a) to move the base end of the cantilever in the negative z-direction such that the measuring tip in the test region of the sample is made to approach the sample up to a final z-distance in relation to the z-direction. Furthermore, a plurality of approach curves are ascertained on the basis of in each case different final z-distances of the measuring tip from the sample in relation to the z-direction and mutually offset x- and/or y-positions of the measuring tip. Moreover, in a manner assigned to each ascertained approach curve, at least one image of the sample in which the test region is at least partially captured is received. Whether the sample in the test region is damaged is then ascertained for each received image. Moreover, a minimal deflection (and hence a minimal distance) of the approach curve which is based on the smallest final z-distance of the measuring tip from the sample for which the sample is established as not being damaged in the test region on the basis of the corresponding image is stored as a safe deflection of the free end of the cantilever.

According to a further embodiment:
a plurality of approach curves are ascertained on the basis of a plurality of in each case different test regions which differ from one another in terms of a type of material of the test region,
at least one image is received, in which the plurality of test regions are at least partially captured,
whether the sample is damaged in the respective test region is ascertained for each ascertained approach curve on the basis of the at least one received image, and
a minimal z-deflection and/or a minimal z-distance of the respective approach curve is stored in a manner dependent on the corresponding material of the respective test region as a safe z-deflection of the free end of the cantilever or as a safe z-distance of the base end of the cantilever from the sample should the sample be ascertained as being undamaged in the respective test region.

For example, in a manner assigned to each ascertained approach curve, at least one image in which the respective test region is at least partially captured is received. Alternatively, two, more or all test regions are imaged in the image detail of an image.

The different test regions which differ from one another in terms of a type of a material of the test region, for example, contain a material that corresponds to a material of structures (e.g., absorber structures) of the sample, a material that corresponds to a material of a substrate of the sample and a material that corresponds to a capping layer, covering layer and/or protective layer (e.g., capping layer of an EUV mask) of the sample.

According to a further embodiment, the nanomanipulator preferably comprises a sample stage device having a mount, a sample stage arranged movably on the mount and a further positioning unit for moving the sample stage relative to the mount. Moreover, the method includes:
8a) controlling the positioning unit to move the measuring tip in the negative z-direction such that the measuring tip is brought into contact with the sample, and
8b) controlling the positioning unit and/or the further positioning unit to move the measuring tip and/or the sample arranged on the sample stage such that the measuring tip and the sample are brought to a predetermined distance from one another.

As a result—starting from contact between the measuring tip and the sample (e.g., a surface of the sample)—the measuring tip can be removed from the sample by the predetermined distance. Hence, a predetermined fixed working distance can advantageously be applied between the measuring tip and the sample (i.e., in the z-direction). The fixedly predetermined working distance improves the reproducibility of image recordings (e.g., made by a scanning electron microscope and/or a scanning ion microscope) of the sample, in which the measuring tip is at least partially captured. Image-monitored processing processes can be improved as a result. For example, the image-monitored processing processes relate to manipulation processes with the aid of the measuring tip (e.g., a displacement of particles on the sample and/or removal of particles from the sample) and/or particle beam-induced processes (e.g., electron beam-induced processes and/or ion beam-induced processes), e.g., etching processes and deposition processes.

Moreover, the predetermined distance can be chosen such that a drift movement of the measuring tip relative to the sample does not lead to sample damage, e.g., damage to the structures of the sample. A drift movement of the measuring tip relative to the sample may arise due to thermal drifts (e.g., heating up of the measuring tip and/or of the cantilever) or charging processes of the sample surface on account of processing with a particle beam (e.g., imaging by a scanning electron microscope). This increases a force between measuring tip and sample, leading to the drift movement. So-called “subsequent creeping” of the measuring tip when moving to a specific position on the sample is also known.

In a first variant, the predetermined distance between the measuring tip and the sample can be set by controlling the positioning unit to move the base end of the cantilever, and hence the measuring tip, away from the sample. Alternatively, the predetermined distance between the measuring tip and the sample can be set in a second variant by controlling the further positioning unit of the sample stage device to move the sample stage, and hence the sample arranged on the sample stage, away from the measuring tip in the negative z-direction.

For example, steps 8a) and 8b) are carried out by the control apparatus.

In embodiments, the nanomanipulator comprises a deflection detection device (e.g., a light pointer device) for detecting a deflection of the free end of the cantilever in a z-direction, which is arranged perpendicular to the x- and the y-direction. Moreover, an extent of the deflection of the free end of the cantilever in the z-direction is received by the deflection detection device in step 8a). Furthermore, the positioning unit is controlled in step 8a) to move the base end of the cantilever in the negative z-direction such that the measuring tip is made to approach the sample until the received extent of the deflection corresponds to a predetermined extent of the deflection. In particular, the predetermined extent of the deflection corresponds to contact between the measuring tip and the sample (e.g., the surface of the sample).

According to a further embodiment, the method includes:
9a) providing a removal trajectory for removing a particle arranged on the sample, wherein the removal trajectory lies in an xy-plane that is spanned by the x- and the y-direction and intersects an xy-position of the particle,
9b) controlling the positioning unit to position the measuring tip at a first predetermined z-distance from the sample in relation to the z-direction,
9c) controlling the positioning unit to laterally move the measuring tip along the ascertained removal trajectory and at the first predetermined z-distance from the sample,
9d) controlling the positioning unit to move the measuring tip away from the sample in the positive z-direction,
9e) ascertaining as to whether the particle adheres to the measuring tip, and
9f) repeating steps 9b) to 9e) for one or more further predetermined z-distances which are increasingly smaller than the first predetermined z-distance, until the particle is ascertained as adhering to the measuring tip,
wherein steps 9b) to 9f) are carried out fully automatically.

The removal of particles from the sample requires nanometer-scale manipulations in particular. The proposed particle removal process allows a particle to be removed from the sample in fully automated fashion, i.e., without the action of a user. In particular, a predetermined removal trajectory is applied, which is a path and/or trajectory along which the measurement tip is moved in order to make contact with the particle. One could also say that the removal trajectory is an access path of the measuring tip for making contact with the particle. In particular, the predetermined removal trajectory (which is arranged in an xy-plane in particular) can be successively traversed in fully automated fashion by the measuring tip at different z-distances from the sample. In that case, a z-distance between the measuring tip and the sample is progressively and incrementally reduced. This allows the measuring tip to make contact with the particle as far down as possible (i.e., as close as possible to the sample surface) without damaging the measuring tip and/or the sample. In particular, the incremental reduction in the z-distance between the measuring tip and the sample is advantageous in that physical contact between the measuring tip and/or the sample is prevented to the greatest possible extent, and it is hence possible to avoid damage to the measuring tip and/or the sample.

For example, a user merely needs to start the particle removal process—e.g., by use of a human-machine interface (HMI). For example, the human-machine interface comprises a keyboard, a mouse pointer, joystick, game controller, touchscreen or the like. Steps 9b) to 9f) are carried out in fully automated fashion by starting the particle removal process. In particular, starting the particle removal process causes the measuring tip to be moved in fully automated fashion at the various z-distances, initially in the lateral direction along the removal trajectory (step 9c) and then in the positive z-direction away from the sample (step 9d), until the particle adheres to the measuring tip.

For example, the first predetermined z-distance is 50 nm, 40 nm or 30 nm. For example, the one or more further predetermined z-distances are 5 nm, 10 nm or 15 nm smaller than an immediately preceding z-distance (i.e., than the first or the further predetermined z-distance). Purely by way of example, the first predetermined z-distance is 50 nm, a second predetermined z-distance is 40 nm, a third predetermined z-distance is 30 nm, a fourth predetermined z-distance is 20 nm and a fifth predetermined z-distance is 10 nm.

Step 9f) is not carried out should the particle already be ascertained as adhering to the measuring tip at the first z-distance in step 9e).

A lateral movement of the measuring tip is a movement of the measurement tip in the x- and/or y-direction (in other words in the xy-plane) in particular. For example, the measuring tip is moved only in the x-direction, only in the y-direction or simultaneously in the x- and the y-direction.

The x- and the y-position of the particle accordingly are positions in relation to the x- and the y-direction.

For example, the removal trajectory is a linear removal trajectory.

For example, steps 9a) to 9f) are carried out by the control apparatus.

In embodiments, ascertaining the removal trajectory includes:
receiving an image of at least one part of the sample, wherein the particle arranged on the sample surface is captured in the image,
ascertaining, on the basis of the received image, the removal trajectory for removing the particle.

In embodiments, a linear removal trajectory for the particle to remove the particle is ascertained in such a way that the removal trajectory intersects the particle, a length of the removal trajectory is longer than a size of the particle and the removal trajectory is free of structures of the sample.

In embodiments, a linear removal trajectory for the particle to remove the particle is ascertained in such a way that on one side of the particle the removal trajectory projects beyond the particle by double the size of the particle. Additionally or instead, the removal trajectory is ascertained, for example, in such a way that on the other side of the particle the removal trajectory projects beyond the particle by one and a half times a diameter of the measuring tip.

In embodiments, the method includes: automatically monitoring one or more parameters, for example, a deflection of the free end of the cantilever in the z-direction, a twist of the free end of the cantilever around the x-direction, and/or a bending of the measuring tip relative to the cantilever. Further, the positioning unit is controlled to stop a lateral movement of the measuring tip and/or to withdraw the measuring tip in relation to the sample (i.e., in the positive z-direction) should the current state of the one or more parameters be ascertained as outside of a permitted region.

For example, in step 9b), the positioning unit is controlled in such a way that the measuring tip (i.e., the apex of the measuring tip) is positioned in relation to the x- and y-direction on a point on the removal trajectory.

According to a further embodiment, step 9c) includes:
controlling the positioning unit to laterally move the measuring tip along the ascertained removal trajectory in steps of a first predetermined lateral distance and preferably in steps of one or more further predetermined lateral distances, which are increasingly greater than the first predetermined lateral distance.

As a result of progressively increasing the increment during the lateral movement of the measuring tip, it is possible to laterally apply a progressively greater force in order to attempt to break a particle free. However, since this harbors the risk of damaging the sample and/or the measuring tip at the same time, the lateral distance is only increased incrementally. This can ensure that the amount of force applied is only as much as is required to detach the particle.

For example, the first predetermined lateral distance is 10 nm, 20 nm or 30 nm. The one or more further predetermined lateral distances are 30 nm, 40 nm, 50 nm, 60 nm and/or 70 nm, for example.

According to a further embodiment, the method includes:
9a′) controlling the positioning unit to position the measuring tip on a surface of the sample adjacent to a particle on the surface, wherein a base point of the cantilever is situated in relation to the z-direction at a first predetermined z-distance from the sample,
9b′) controlling the positioning unit to laterally move the measuring tip in order to detach the particle from the surface,
9c′) ascertaining whether the particle has moved on the surface, and
9d′) repeating steps 9a′) to 9c′) for one or more further predetermined z-distances which are between the base point of the cantilever and the sample and which are increasingly smaller than the first predetermined z-distance, until the particle is ascertained as having moved on the surface,
wherein steps 9a′) to 9d′) are carried out fully automatically.

By repeating steps 9a′) to 9c′) for progressively smaller z-distances between the base point of the cantilever and the sample, an incrementally increasing force is applied to the measuring tip, and hence to the particle, until the particle has detached from the surface. As a result, the amount of force applied can be only as much as is required to detach the particle from the surface. At the same time, an unnecessarily high exertion of force is avoided, whereby damage to the measuring tip and/or the sample can be prevented.

According to a further embodiment, the method includes:
12a) controlling the positioning unit to laterally move the measuring tip in the direction of a particle arranged on the sample,
12b) ascertaining as to whether the particle adheres to the measuring tip, and
12c) controlling the positioning unit to move the measuring tip away from the sample in the positive z-direction and/or to move the measuring tip along a curved trajectory, which in the region of the particle curves from an initially lateral movement into a movement in the positive z-direction, should the particle be ascertained as adhering to the measuring tip,
wherein steps 12a) to 12c) are performed fully automatically.

As a result, a move and lift process of the measuring tip, as may be required for picking a particle up from the sample surface, can be carried out fully automatically. In particular, it is possible to fully automatically ascertain whether the particle adheres to the measuring tip. Furthermore, should the particle be confirmed as adhering to the measuring tip, the measuring tip is moved away from the sample in the positive z-direction (step 12c) and hence the particle is lifted from the sample surface; this is implemented fully automatically.

For example, steps 12a) and 12b) are repeated simultaneously and/or repeatedly. For example, steps 12a) to 12c) are carried out by the control apparatus.

In step 12a), the positioning unit is controlled, in particular to linearly laterally move the measuring tip in the direction of the particle arranged on the sample and/or to move the measuring tip along the curved trajectory.

According to a further embodiment, the method includes:
controlling the positioning unit to move the measuring tip in the lateral direction and/or in the positive z-direction in order to pick up a particle arranged on the sample using the measuring tip,
ascertaining as to whether the particle adheres to the measuring tip on the basis of:
   an extent of a lateral deflection of the cantilever received from a deflection detection device,
   a plurality of received images of at least one part of the sample, the images capturing the particle, and a change in the brightness of the particle and/or a change in the contrast of the particle relative to the measuring tip in the plurality of images, as ascertained by use of image processing,
   a plurality of images of at least one part of the sample, the images being received from an image recording device and capturing the particle, and a migration of the particle out of a fixedly set focus of the image recording device, as ascertained by use of image processing of the plurality of images, and/or
   information that is received from an image recording device which records images of at least one part of the sample, in which the particle is captured, with an autofocus setting focused on the particle and that relates to an extent of an automatic adjustment of the autofocus focused on the particle, the adjustment being greater than a predetermined threshold value.

As a result, whether the particle adheres to the measuring tip can be ascertained according to one, more or all of four different variants (first to fourth variants). In particular, as a result it is possible in each case to, for example, fully automatically ascertain whether the particle adheres to the measuring tip.

For example, the particle can be moved laterally by use of the measuring tip until an indication for an adherence according to one or more of the first to fourth variants is ascertained. Thereupon, the measuring tip can be moved in the positive z-direction (i.e., lifted), wherein a check is carried out with the aid of one or more of the first to fourth variants as to whether the particle is lifted off together with the measuring tip (i.e., remains adhering to the measuring tip) or not (i.e., detaches from the measuring tip again).

For example, the control apparatus receives the extent of the deflection detected by the deflection detection device. For example, the control apparatus receives the one or more images recorded by the image recording device. For example, in accordance with one, more or all of the four different variants, the control apparatus ascertains whether the particle adheres to the measuring tip.

In the first variant, whether the particle adheres to the measuring tip is ascertained on the basis of an extent of the deflection of the cantilever in the lateral direction, which is received from the deflection detection device. The extent of the deflection of the cantilever in the lateral direction can, for example, be ascertained on the basis of an extent of a twist of the cantilever. For example, the measuring tip is ascertained as having contact with the particle should the extent of the deflection of the cantilever in the lateral direction be greater than a predetermined threshold value.

In the second variant, whether the particle adheres to the measuring tip is ascertained on the basis of a change in the brightness and/or a change in the contrast of the particle in images (e.g., electron microscope images and/or ion microscope images) of the particle. For example, at least one part of the measuring tip is also captured in the plurality of received images of the sample, in addition to the particle. For example, the change in the brightness of the particle is a change of a brightness of the particle relative to a brightness of the measuring tip in the images. For example, the change in the contrast of the particle is a change of a contrast between the particle and the measuring tip in the images. For example, in comparison with the case in which the particle does not adhere to the measuring tip, the brightness of the particle increases when the particle adheres to the measuring tip.

For example, adherence of the particle to the measuring tip leads to electric charging of the particle, whereby the particle becomes brighter in the image. For example, a detachment of the particle from the measuring tip leads to the particle becoming darker again in the image.

In the third variant, the particle adhering to the measuring tip and consequently being lifted (moved in the positive z-direction) together with the measuring tip is ascertained on the basis of a migration of the particle out of a fixedly set focus of the image recording device. In particular, what is ascertained here on the basis of the images is that the particle initially is in a focus of the image recording device (i.e., the focus is adjusted to the particle), and the particle no longer is in the focus of the image recording device in later images.

In the fourth variant, the images of the particle are recorded using an autofocus setting that is focused on the particle. Furthermore, what follows from an automatic adjustment by more than the predetermined threshold value of the autofocus focused on the particle is that a z-position of the particle has changed significantly, and this indicates a lifting of the particle together with the measuring tip (in the positive z-direction).

In the fourth variant, it is possible to optionally ascertain whether the autofocus adjusted to the particle changes in accordance with a movement of the measuring tip in the positive z-direction. The movement of the measuring tip in the positive z-direction is, for example, ascertained with the aid of position data relating to the base end of the cantilever, which are received by the positioning unit.

According to a further embodiment, the nanomanipulator comprises a sample stage device having a mount, a sample stage arranged on the mount so as to be laterally movable and a further positioning unit for laterally moving the sample stage relative to the mount in the x- and the y-direction. Furthermore, the method includes:
14a) controlling the positioning unit to position the measuring tip in a lateral initial position, preset in the positioning unit, in relation to the x- and the y-direction,
14b) receiving at least one image of the sample in which a particle arranged on the sample is captured,
14c) ascertaining, on the basis of image processing, a lateral position of the particle captured in the at least one image, and
14d) controlling the further positioning unit to laterally move the sample stage with the sample, in such a way that the lateral position of the particle corresponds to the lateral initial position of the measuring tip in relation to the x- and the y-direction, and
steps 14a) to 14d) are carried out fully automatically.

As a result, the measuring tip can initially be brought into its preset initial position. Moreover, the particle to be processed can be arranged below the measuring tip, i.e., at the same x- and y-position as the measuring tip. This facilitates processing of the particle using the measuring tip. For example, the measuring tip has only a small limited lateral range (e.g., ±20 μm in the x- and the y-direction) within which it can be displaced. Therefore, it is advantageous to fully automatically arrange the particle below the measuring tip at the same x- and y-coordinates as the measuring tip, and at the same time arrange the measuring tip at its origin position. As a result, there is sufficient space around the particle in the x- and the y-direction for displacing the measuring tip in such a way that the particle can be picked up by the measuring tip. Especially if a plurality of particles arranged on the sample are too far apart to be reached by the measuring tip by only moving the measuring tip, it is advantageous to automatically displace the sample stage accordingly.

Fully automatically arranging the particle below the measuring tip at the same x- and y-coordinates as the measuring tip and simultaneously arranging the measuring tip at its origin position is therefore also advantageous because the particle is in the field of view of the image recording device as a result.

The initial position of the measuring tip in relation to the x- and the y-direction, preset in the positioning unit, is for example an origin position of the measuring tip, which is preset in the positioning unit. The initial position or origin position, for example, corresponds to an origin of the coordinate system of the positioning unit (x=0, y=0).

For example, steps 14a) to 14d) are carried out by the control apparatus.

In embodiments, the method includes:
controlling an image recording device to record one or more first images of at least one part of the sample, in which the measuring tip is at least partially captured,
ascertaining, on the basis of image processing, a position of the measuring tip (lateral position, x- and/or y-position, e.g., position of the apparent apex of the measuring tip) in the one or more first images, and
controlling the image recording device to record one or more further images of at least one part of the sample in which the measuring tip captured in the first image(s) is arranged at a predetermined position in the image (e.g., in an image center).

As a result, the measuring tip, in the course of repeated recording of images, can be automatically kept at a predetermined position in the one or more further images (e.g., in an image center) (referred to as: tip tracking).

For example, a lateral position (i.e., an x- and/or y-position) of the measuring tip is ascertained on the basis of image processing of the first image or the first images.

For example, a position (e.g., lateral position or x- and/or y-position) of the apparent apex of the measuring tip is ascertained on the basis of image processing of the first image or the first images. Furthermore, the image recording device, for example, is controlled to record one or more further images of at least one part of the sample in which the apex of the measuring tip captured in the first image(s) is arranged at a predetermined position in the image (e.g., in an image center).

According to a further aspect, a computer-implemented method for processing a sample using a nanomanipulator is proposed. The nanomanipulator comprises a measuring tip for processing the sample and a positioning unit for moving the measuring tip. Furthermore, the sample is arranged on a sample stage. An x-direction and a y-direction of the nanomanipulator are each arranged parallel to a main extension plane of the sample and/or sample stage and perpendicular to one another. The sample has a nanostructure on its surface for the purpose of ascertaining an actual apex of the measuring tip. The method comprises the following steps:
15a) controlling the positioning unit to laterally move the measuring tip from lateral initial coordinates to the lateral end coordinates in order to scan the nanostructure and create raster-scan data,
15b) ascertaining nanostructure coordinates of a highest point of the nanostructure in the raster-scan data,
15c) ascertaining a first lateral distance between the nanostructure coordinates and the lateral end coordinates,
15d) recording at least one image of the sample in which the measuring tip and the nanostructure are at least partially captured, wherein the measuring tip is situated at the lateral end coordinates,
15e) ascertaining a second distance of an apparent apex of the measuring tip from the nanostructure, and
15f) ascertaining a position of an actual apex of the measuring tip on the basis of a difference between the first and the second distance.

As a result, it is possible to ascertain a position (e.g., x- and y-position) of the actual apex of the measuring tip, even if only the apparent apex of the measuring tip is visible in the recorded and received image. In particular, the actual apex of the measuring tip might not be visible in the image because it is concealed in relation to a line-of-sight of the image recording device.

The nanostructure for ascertaining the actual apex of the measuring tip, for example, has a lateral dimension of 30 nm or less, 20 nm or less, 10 nm or less and/or 5 nm or less.

The nanostructure for ascertaining the actual apex of the measuring tip, for example, has a spherical shape, hemispherical shape and/or spherical surface. Alternatively, the nanostructure for ascertaining the actual apex of the measuring tip might, for example, also have a tip, in particular a tip that tapers in a direction going away from the sample surface.

According to a further aspect, a computer program product is proposed, comprising instructions which, upon execution of the program by at least one computer, cause the latter to carry out one of the methods described above.

A computer program product, such as e.g. a computer program means, can be provided or supplied, for example, as a storage medium, such as e.g. a memory card, a USB stick, a CD-ROM, a DVD, or else in the form of a downloadable file from a server in a network and/or from a cloud-based source. For example, in a wireless communications network, this can be effected by transferring an appropriate file with the computer program product or the computer program means.

According to a further aspect, an apparatus for processing a sample is proposed. The apparatus comprises:
a nanomanipulator having a measuring tip for processing the sample and a positioning unit for moving the measuring tip,
a sample stage for arrangement of the sample, wherein an x-direction and a y-direction of the nanomanipulator are each arranged parallel to a main extension plane of the sample and/or sample stage and perpendicular to one another, and
a control apparatus configured to carry out the method described above.

The main extension plane of the sample and/or sample stage is, for example, an xy-plane spanned by the x-direction and the y-direction.

The apparatus for processing a sample, for example, comprises a sample stage device having a mount, wherein the sample stage is arranged movably on the mount. Moreover, the sample stage device comprises, e.g., a further positioning unit for moving the sample stage relative to the mount. The sample stage can be moved, for example, with the aid of the further positioning unit in the x-direction and the y-direction (i.e., laterally) and/or in the z-direction (vertical direction). The sample stage can, for example, also be mounted rotatably on the mount, such that it can be rotated about the x-, y- and/or z-direction with the aid of the further positioning unit. The sample stage comprises in particular a surface for arrangement of the sample.

The respective unit, for example, the control apparatus, can be implemented in terms of hardware technology and/or else software technology. In the case of an implementation in terms of hardware technology, the respective unit can be embodied as an apparatus or as part of an apparatus, for example, as a computer or as a microprocessor. In the case of an implementation in terms of software technology, the respective unit can be embodied as a computer program product, as a function, as a routine, as part of a program code or as an executable object.

“A(n)” should not necessarily be understood as a restriction to exactly one element in the present case. Rather, a plurality of elements, such as for example two, three or more, can also be provided. Nor should any other numeral used here be understood to the effect that there is a restriction to exactly the stated number of elements. Rather, unless indicated otherwise, numerical deviations upwards and downwards are possible. The numbering of features in the claims, for example, 1a, 1b, 6a, 6b, etc. does not imply any order, neither within one claim nor in the combination of a plurality of claims. For example, unless indicated otherwise, step 6b can be implemented before step 6a. Also, “first”, “second”, etc. are used only to distinguish elements from one another. For example, a “third” (or any other) element does not required a “first” or “second” (or any other) element to be present in the claim. Also, the “second” or “third” (or any other) element may be renamed as the “first” (or any other) element.

The embodiments and features described for one or more method aspects apply correspondingly to the proposed apparatus aspects, and vice versa. Also, the above method aspects and/or the above apparatus aspects may be combined with each other.

Further possible implementations of the invention also comprise non-explicitly mentioned combinations of features or embodiments described previously or hereinafter with regard to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in detail hereinafter on the basis of preferred embodiments with reference to the accompanying figures.

### BRIEF DESCRIPTION OF DRAWINGS

FIG. 1 shows an apparatus for analyzing and/or processing a sample, according to one embodiment;

FIG. 2 shows an enlarged portion of the apparatus from FIG. 1 together with a light pointer device, according to one embodiment;

FIG. 3 shows an image of a portion of a sample to be processed by the apparatus from FIG. 1, according to one embodiment;

FIG. 4 shows a cross section from FIG. 3 along the line IV-IV;

FIG. 5 shows an enlarged view of a measuring tip of the apparatus from FIG. 1, according to one embodiment;

FIG. 6 shows an image of a portion of a sample and the measuring tip from FIG. 5, according to one embodiment;

FIG. 7 shows a view similar to FIG. 6, wherein the measuring tip has left a first track in a test region of the sample, according to one embodiment;

FIG. 8 shows a view similar to FIG. 7, wherein a first straight line has been fitted to the first track, according to one embodiment;

FIG. 9 shows a view similar to FIG. 8, wherein the measuring tip has left a second track in a test region of the sample, and a second straight line has been fitted to the second track, according to one embodiment;

FIG. 10 shows an approach curve, which plots a deflection of a free end of a cantilever of the apparatus from FIG. 1 as a function of a distance of a base end of the cantilever, according to one embodiment;

FIG. 11 shows an image of a portion of a sample with three test regions, according to one embodiment;

FIG. 12 shows a view similar to FIG. 10, wherein three approach curves are shown for the three test regions in FIG. 11, according to one embodiment;

FIG. 13 elucidates automatic positioning of the measuring tip in a predetermined working distance from a sample, according to one embodiment;

FIG. 14 elucidates a fully automatic iterative particle removal process, according to one embodiment;

FIG. 15A shows different lateral distances which are applied during the fully automatic iterative particle removal process from FIG. 14, according to one embodiment;

FIG. 15B shows different z-distances which are applied during the fully automatic iterative particle removal process from FIG. 14, according to one embodiment;

FIGS. 16A to 16C elucidate a further fully automatic iterative particle removal process, according to one embodiment;

FIG. 17 elucidates a first variant of a process in which a check is carried out as to whether a particle adheres to the measuring tip, according to one embodiment;

FIG. 18 elucidates a second variant of a process in which a check is carried out as to whether a particle adheres to the measuring tip, according to one embodiment;

FIG. 19 shows a change in the brightness of a particle adhering to a measuring tip within the second variant of the process from FIG. 18, according to one embodiment;

FIG. 20 elucidates a third variant of a process in which a check is carried out as to whether a particle adheres to the measuring tip, according to one embodiment;

FIG. 21 elucidates a fourth variant of a process in which a check is carried out as to whether a particle adheres to the measuring tip, according to one embodiment;

FIG. 22 shows a flowchart of a computer-implemented method for processing a sample using the apparatus from FIG. 1, according to one embodiment;

FIG. 23 shows a flowchart of a computer-implemented method for processing a sample using the apparatus from FIG. 1, according to a further embodiment;

FIG. 24 shows a flowchart of a computer-implemented method for processing a sample using the apparatus from FIG. 1, according to a further embodiment;

FIG. 25 shows a flowchart of a computer-implemented method for processing a sample using the apparatus from FIG. 1, according to a further embodiment;

FIG. 26 elucidates a computer-implemented method for ascertaining an actual apex of a measuring tip, according to one embodiment, wherein FIG. 26 shows a sample having a nanostructure for ascertaining the actual apex of the measuring tip and the measuring tip;

FIG. 27 shows a recorded image, in which the sample having the nanostructure and the measuring tip from FIG. 26 are captured, according to one embodiment;

FIG. 28 elucidates a further embodiment of a nanostructure for ascertaining the actual apex of the measuring tip;

FIG. 29 shows a flowchart of a computer-implemented method for processing a sample using the apparatus from FIG. 1, according to a further embodiment;

FIG. 30 shows a schematic diagram of a system for detecting a frequency shift of a driving signal, according to a further embodiment;

FIG. 31 shows a schematic diagram of a beam deflection system;

FIG. 32 shows resonance curves of a probe in vacuum and air, respectively;

FIG. 33 illustrates a method for detecting an interaction between a probe and a sample based on tracking an amplitude signal;

FIG. 34 illustrates a method for detecting an interaction between a probe and a sample based on tracking a frequency signal, according to a further embodiment;

FIG. 35 shows a flowchart of a computer-implemented method for landing a probe of a nanomanipulator on a sample using the system from FIG. 30, according to one embodiment; and

FIG. 36 shows different images provided by an apparatus for aiding a user during particle removal.

### DETAILED DESCRIPTION

Unless indicated otherwise, elements that are identical or functionally identical have been provided with the same reference signs in the figures. Furthermore, it should be noted that the illustrations in the figures are not necessarily true to scale.

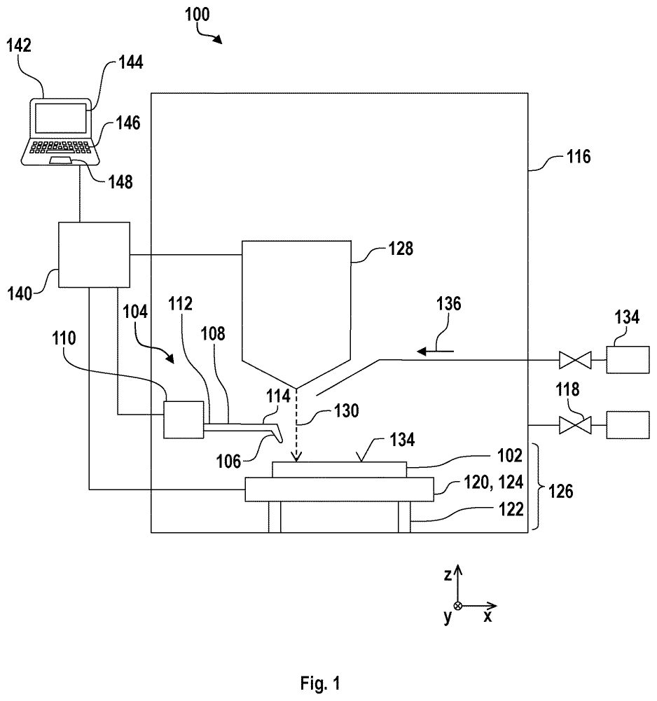

FIG. 1 schematically shows one exemplary embodiment of an apparatus 100 for analyzing and/or processing a sample 102 with the aid of an atomic force microscope 104 as one example of a nanomanipulator. The atomic force microscope 104 comprises a measuring tip 106 for analyzing and/or processing the sample 102. The measuring tip 106 is arranged on a cantilever 108 secured movably to a positioning unit 110 (movement unit). In particular, the cantilever 108 comprises a first end 112 (base end 112), at which the cantilever 108 is movably secured to the positioning unit 110. Furthermore, the cantilever 108 comprises a second end 114 (free end 114), at which the measuring tip 106 is arranged. With the aid of the positioning unit 110, the measuring tip 106 can be moved in three spatial directions x, y, z (translational movement in x-, y- and z-directions). Movements in the x- and/or y-direction are referred to as lateral movements herein. Herein, movements in the z-direction are referred to as an approach of the sample 102 by the measuring tip 106 (negative z-direction) and a removal/away movement of the measuring tip 106 from the sample 102 (positive z-direction).

The apparatus 100 comprises a housing 116 which can be evacuated to a residual gas pressure of 10⁻⁵-10⁻⁹ mbar, for example, by use of a vacuum pump 118. The atomic force microscope 104 is arranged in the housing 116. Furthermore, a sample stage 120 for holding the sample 102 is provided. The sample stage 120 is preferably held by the housing 116 by use of a mount 122. The sample stage 120 can furthermore comprise a further positioning unit 124 (not illustrated individually), by use of which the sample stage 120 is displaceable relative to the mount 122 in the three spatial directions x, y and z, for example, and is rotatable about at least one axis (e.g., an axis arranged parallel to the z-direction in FIG. 1), for example. Reference sign 126 denotes a sample stage device which comprises the sample stage 120, the mount 122 and the further positioning unit 124.

Moreover, a particle beam column (corpuscular beam column) 128, for example, is arranged in the housing 116. The particle beam column 128 is configured to provide a particle beam 130. The particle beam column 128 can be designed in particular as a particle beam microscope and can be used to monitor processing of the sample 102 using the measuring tip 106.

For example, the particle beam column 128 is an electron column 128, which is configured to provide an electron beam 130. In particular, the electron column 128 can be designed as an electron microscope. By way of example, the particle beam column 128 is described as electron column 128 below.

However, the particle beam column 128 could also be an ion column (not shown) in other examples, which is configured to provide an ion beam.

In conjunction with a process gas providing unit 134, the electron column 128 can additionally be used for conducting particle beam-induced processing processes on the sample 102. For this purpose, for example, a process gas 136 is supplied by use of the process gas providing unit 134, and is irradiated by the particle beam 130.

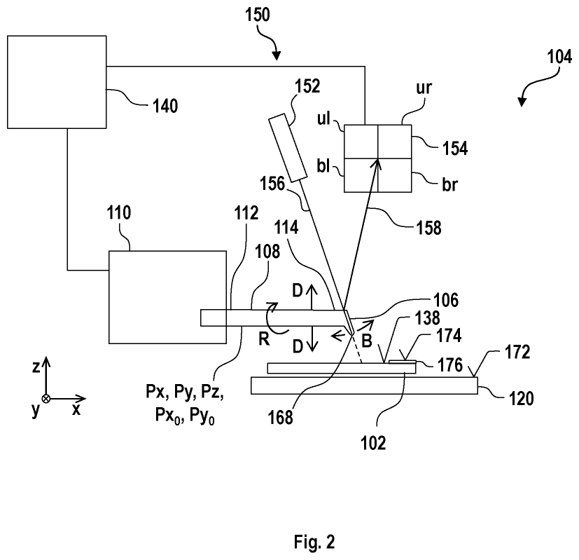

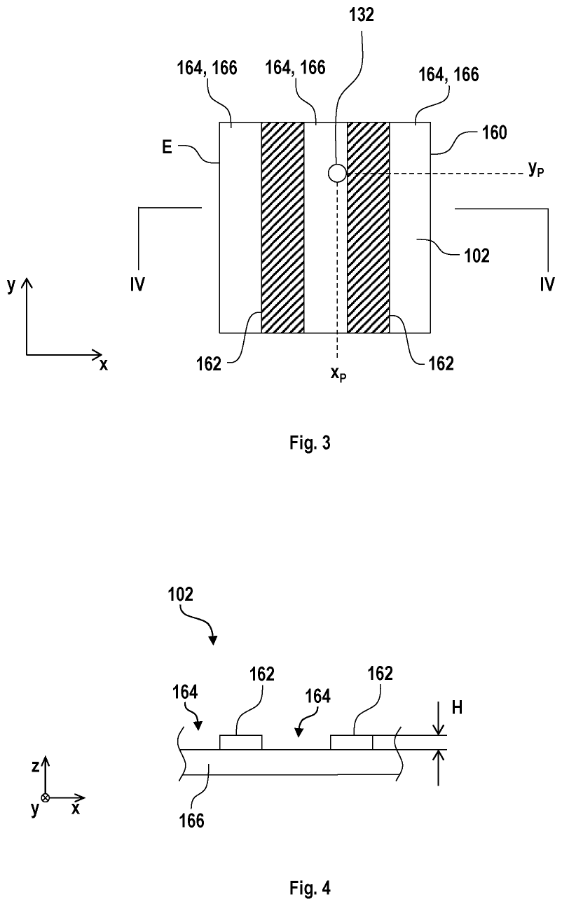

A particle 132 (FIG. 3) adhering on a sample surface 138 (FIG. 2) of the sample 102 can be picked up with the measuring tip 106. For this purpose, the measuring tip 106 is correspondingly moved, for example, by use of the positioning unit 110. For assistance, the sample stage 120 can also be displaced by use of its further positioning unit 124. The picking up of the particle 132 by the measuring tip 106 is monitored live in particular with the electron microscope 128.

Afterwards, the measuring tip 106 is moved by use of the positioning unit 110 to a repository unit (shown), where the particle 132 is transferred from the measuring tip 106 to the repository unit.

FIG. 1 additionally shows a control apparatus 140 for controlling the atomic force microscope 104 (e.g., the positioning unit 110), the sample stage 120 or the further positioning unit 124, the electron microscope 128 and/or the process gas providing unit 134. A human-machine interface 142 can be provided as part of the control apparatus 140 or in a manner connected to the control apparatus 140 in wired or wireless fashion for data transfer. The human-machine interface 142 comprises, for example, a display device 144, a loudspeaker (not shown), a keyboard 146, a mouse pointer 148, a joystick, a game controller (not shown) or the like.

As shown in FIG. 2, the atomic force microscope 104 can, for example, comprise a deflection detection device 150 (e.g., a light pointer device 150) for detecting an extent of the deflection D of the free end 114 of the cantilever 108 in the z-direction. In particular, the z-direction is arranged perpendicular to the sample 102 or to a main extension plane E (xy-plane in FIG. 3) of the sample 102 and/or of the sample stage (120). The deflection D of the free end 114 of the cantilever 108 in the z-direction is caused by forces acting between the measuring tip 106 and the sample 102 and is proportional to a spring constant of the cantilever 108. A force acting on the cantilever 108 in the z-direction can thus be ascertained by detecting the deflection D.

The light pointer device 150 can also be used for detecting an extent of a rotation R of the free end 114 of the cantilever 108 about the x-direction. A rotation R (twist R; see FIG. 2) of the free end 114 of the cantilever 108 about the x-direction can be caused by lateral forces that act between the measuring tip 106 and the sample 102.

The light pointer device 150 comprises, for example, a laser source 152 and a position-sensitive photodetector 154. A laser beam 156 emitted by the laser source 152 is directed at the free end 114 of the cantilever 108 and reflected from there onto the photodetector 154. The photodetector 154 comprises, for example, four photosensitive regions ul, ur, bl and br. In an undeflected position of the cantilever 108, the laser beam 156, 158 is reflected into the center of the photodetector 154, as shown in FIG. 2. However, if the cantilever 108 is deflected in a positive or negative z-direction (deflection D), then the reflected laser beam 158 migrates on the photodetector 154 as in the case of a light pointer. By measuring the received intensities in the four regions ul, ur, bl and br of the photodetector 154, it is possible to determine vertical and horizontal deflection signals (bending signals) of the cantilever 108. The deflection signals are proportional to forces acting on the cantilever 108 in the z-direction (normal force) and also to lateral forces acting in the x-direction or y-direction.

For example, a bending B (FIG. 2) of the measuring tip 106 relative to the cantilever 108 can also be ascertained in the method. In particular, interaction of the measuring tip 106 with the sample 102 can result in a bending B (i.e., an elastic deformation) of the measuring tip 106 relative to the cantilever 108. For example, the measuring tip 106 may bend on account of a lateral movement of the measuring tip 106 (in the x- and/or y-direction in FIG. 2) while the measuring tip 106 is simultaneously in contact with the sample 102. An extent of this bending B of the measuring tip 106 can be ascertained by use of image processing in recorded images 160 of the measuring tip 106.

The illustrated apparatus 100 (FIGS. 1, 2) comprises a number of optional elements which do not necessarily have to be present. These are in particular the housing 116, the vacuum pump 118, the sample stage device 126, the electron column 128 (or an ion column), the process gas providing unit 134, the human-machine interface 142 and the deflection detection device 150.

FIG. 3 shows an image 160 (e.g., a scanning electron microscope image 160, for short: SEM image 160) of a portion of an exemplary sample 102. FIG. 4 shows the portion of the sample 102 shown as image 160 in FIG. 3 in a cross-sectional view along line IV-IV in FIG. 3. The sample 102 comprises, for example, structures 162 (e.g., absorber structures 162) with intervening trenches 164. H denotes height of the structures 162. Moreover, an exemplary particle 132 is shown on the sample 102, which particle lies in one of the trenches 164 at the edge of one of the absorber structures 162 and needs to be removed. The reference sign 166 in FIGS. 3 and 4 denotes a substrate of the sample 102.

Removing particles 132 with the aid of the atomic force microscope 104 requires a manipulation of the measuring tip 106 with an accuracy of the order of magnitude of nanometers. It may be necessary here to move to a particle 132 many times with the measuring tip 106 controlled by a user and to track the procedure in the SEM images 160 until finally adhering of the particle 132 to the measuring tip 106 is achieved and the particle 132 can be removed from the sample 102.

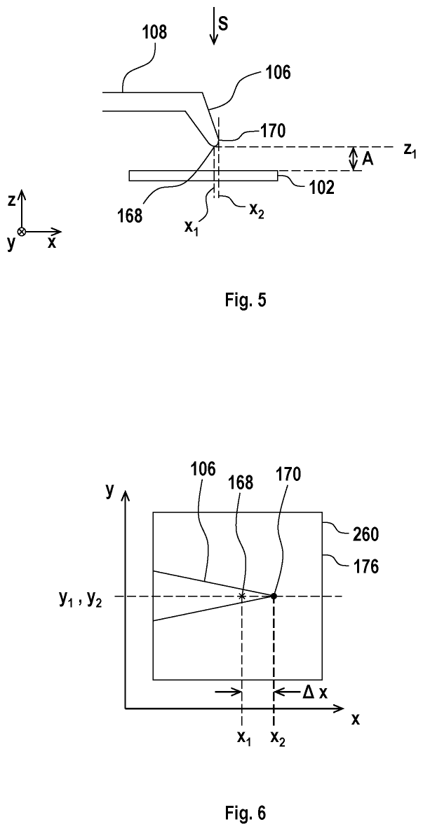

Furthermore, processing the sample 102, in particular removing particles 132 from the sample 102, is made more difficult by the fact that the precise position of an apex 168 (FIG. 2) of the measuring tip 106 is generally unknown. In particular, the apex 168 of the measuring tip 106 is the point and/or region of the measuring tip 106 which makes initial contact with the sample 102 or a particle 132 on the sample 102 when the measuring tip 106 approaches the sample 102 and/or particle 132. On account of the geometry of the measuring tip 106, the actual apex 168 of the measuring tip 106 might not be visible in the SEM images 160, and so the accurate x- and y-position x1, y1 (FIG. 5) of the actual apex 168 cannot be ascertained from an SEM image 160 alone.

FIG. 5 elucidates a measuring tip 106 with a geometry in which the apex 168 is arranged in such a way that the apex 168 is concealed in relation to a line-of-sight S of the scanning electron microscope 128. Consequently, the actual apex 168 will not be visible in an SEM image 260 (FIG. 6). Instead, a point 170 (FIG. 5) of the measuring tip 106 will appear in the SEM image 260 as an apparent apex 170. In the example of FIG. 6, the actual apex 168 is at a lateral position x1, y1, and the apparent apex 170 is at a lateral position x2, y2. In the example of FIG. 6, the y-position y1 of the actual apex corresponds to the y-position y2 of the apparent apex 170. However, the x-position x1 of the actual apex 168 is displaced from the x-position x2 of the apparent apex 170 by a distance Δx.

A computer-implemented method for processing a sample 102 using an atomic force microscope 104 is described below with reference to FIGS. 1 to 25.

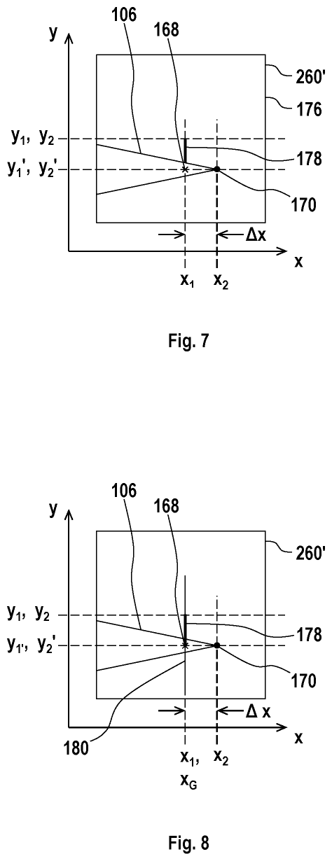

In a first step S1 of the method, the positioning unit 110 is controlled to move the measuring tip 106 in the y-direction such that the apex 168 of the measuring tip 106 is in contact with a surface 172 of the sample stage 120 or a surface 174 of the sample 102 in a test region 176 of the sample stage 120 or sample 102, and the measuring tip 106 leaves a first track 178 (e.g., a scratched track 178) on the surface 172, 174. In particular, the first track 178 is arranged parallel to the y-direction. A test region 176 of the sample 102 is shown in FIG. 6 by way of example. However, the method can also be used for a test region (not shown here) of the sample stage 120 in other examples. As elucidated in FIG. 7, the apex 168 of the measuring tip 106 thus is scratched in the y-direction along the surface 172, 174 of the test region 176 in step S1.

In a second step S2 of the method, the image recording device 128 is controlled to record at least one image 260′ of the test region 176, the first track 178 being at least partially captured therein (FIG. 7).

In a third step S3 of the method, an x-position x1 of the apex 168 of the measuring tip 106 is ascertained in relation to the x-direction on the basis of the first track 178 captured in the image 260′. For example, as shown in FIG. 8, a straight line 180 is fitted to the first track 178. Thereupon, the x-position x1 of the actual apex 168 of the measuring tip 106 is ascertained as the x-position x_{G} of the straight line 180. For example, the x-position x1 of the actual apex 168 is ascertained relative to the x-position x2 of the apparent apex 170 of the measuring tip 106, e.g., as an x-offset Δx.

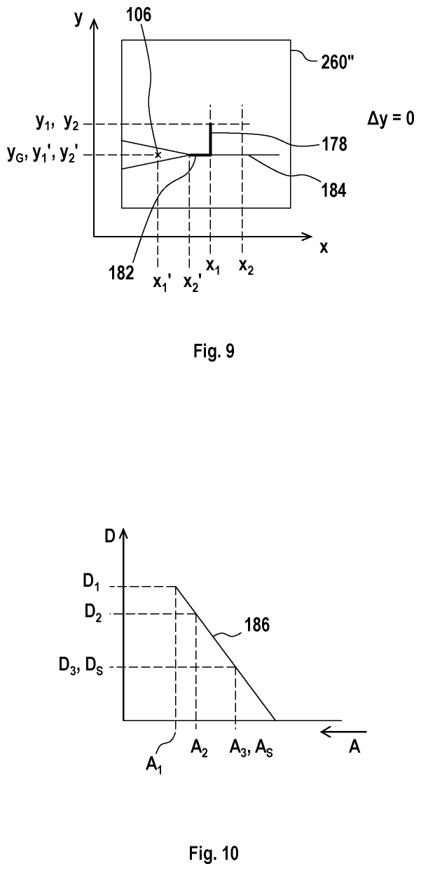

In a fourth step S4 of the method, the positioning unit 110 is controlled to move the measuring tip 106 in the x-direction such that the apex 168 of the measuring tip 106 is in contact with the surface 174 of the sample 102 (or with the surface 172 of the sample stage 120 in other examples) in the test region 176, and the measuring tip 106 leaves a second track 182 (e.g., a scratched track 182) on the surface 174. In particular, the second track 182 is arranged parallel to the x-direction. As elucidated in FIG. 9, the apex 168 of the measuring tip 106 thus is scratched in the x-direction along the surface 174 of the test region 176 in step S4.

In a fifth step S5 of the method, the image recording device 128 is controlled to record at least one further image 260″ of the test region 176, the second track 182 being at least partially captured therein (FIG. 9).

In a sixth step S6 of the method, a y-position y1′ of the apex 168 of the measuring tip 106 is ascertained in relation to the y-direction on the basis of the second track 182 captured in the image 260″ (FIG. 9). For example, as shown in FIG. 9, a straight line 184 is fitted to the second track 182. Thereupon, the y-position y1′ of the actual apex 168 of the measuring tip 106 is ascertained as the y-position y_{G} of the straight line 184. For example, the y-position y1′ of the actual apex 168 is ascertained relative to the y-position y2′ of the apparent apex 170 of the measuring tip 106, e.g., as a y-offset Δy. In the example shown in FIGS. 6 to 9, the y-position y1, y1′ of the actual apex 168 corresponds to the y-position y2, y2′ of the apparent apex 170 of the measuring tip 106, and so the y-offset Δy is equal to zero.

Thus, by way of steps S1 to S6, it is possible to ascertain the precise x- and y-position x1, y1 (x1′, y1′) of the actual apex 168 of the measuring tip 106 (e.g., relative to the apparent apex 170), even though only the apparent apex 170 of the measuring tip is visible in the SEM images 260, 260′, 260″.

Within the scope of the proposed method, it is optionally also possible to ascertain an approach curve 186 (FIG. 10) in relation to a deflection D (FIG. 2) of the cantilever 108 when the measuring tip 106 approaches the sample 102 in a manner parallel to the z-direction. In particular, attractive and/or repulsive forces act on the free end 114 of the cantilever 108 in a manner dependent on the z-position Pz of the base end 112 of the cantilever 108, and the said forces attract the free end 114 of the cantilever 108 to the sample 102 or repulse the said free end therefrom. For the approach curve 186 (FIG. 10) in relation to the deflection D of the free end 114 of the cantilever 108, consideration is given here only to a distance range in relation to the z-direction in which only repulsive forces act on the free end 114 of the cantilever 108 and/or in which a repulsive force is greater than an attractive force.

With the aid of the approach curve 186, it is possible to ascertain a safe deflection D_{S} (FIG. 10) of the free end 114 of the cantilever 108 in the z-direction, for which the sample 102 is not damaged by the measuring tip 106. The safe deflection D_{S} of the free end 114 of the cantilever 108 corresponds in particular to a safe minimal z-distance A_{S} of the base end 112 of the cantilever 108 from the sample 102 (i.e., in the z-direction). Ascertaining the approach curve 186 is advantageous because the precise z-position z1 of the apex 168 (FIG. 5) of the measuring tip 106 is generally unknown. In particular, although the z-position Pz of the base end 112 of the cantilever 108 is set and provided by the positioning unit 110, the precise z-position z1 of the apex 168 of the measuring tip 106 is generally not known on account of the changing deflection D of the free end 114 of the cantilever 108 and on account of a possible bending B of the measuring tip 106 relative to the cantilever 108.

In a first step S1′ of the method, the positioning unit 110 is controlled to move the base end 112 of the cantilever 108 in the negative z-direction. As a result, a z-distance A (FIG. 5) between the base end 112 of the cantilever 108 and the sample 102 is reduced, and the measuring tip 106 is made to approach the sample 302 in a test region 188 (FIG. 11) of the sample 302. In particular, the test region 188 is arranged outside of and/or at a distance from structures 362, 364 (e.g., absorber structures) of the sample 302.

In a second step S2′ of the method, the deflection detection device 150 (e.g., the light pointer device 150, FIG. 2) repeatedly receives information regarding an extent D₁, D₂, D₃ (FIG. 10) of the z-deflection D of the free end 114 of the cantilever 108 as a function of a set z-position Pz of the base end 112 of the cantilever 108 (i.e., as a function of the z-distance A, A₁, A₂, A₃ of the base end 112 of the cantilever 108 from the sample 302; see FIGS. 5 and 10). In particular, step S2′ is performed simultaneously with step S1′. Expressed differently, during the displacement of the measuring tip 106 in the negative z-direction (i.e., while the measuring tip 106 approaches the sample 302), the deflection detection device 150 simultaneously or repeatedly measures the z-deflection D of the free end 114 of the cantilever 108. In the example of FIG. 10, the base end 112 of the cantilever 108 is made to approach the sample 102 up to a distance A₃, at which a force that brings about a deflection D₃ acts on the free end 114 of the cantilever. In particular, the distance A in FIG. 10 reduces from left to right, and so A₃ is smaller than A₂, and A₂ is smaller than A₁.

An approach curve 186 (FIG. 10) is ascertained in a third step S3′ of the method. The approach curve 186 specifies the extent D₁, D₂, D₃ of the deflection D of the free end 114 of the cantilever 108 as a function of the distance A, A₁, A₂, A₃ of the z-position Pz of the base end 112 of the cantilever 108 from the sample 302. As shown in FIG. 10, the deflection D of the cantilever 108 becomes ever smaller, the closer the base end 112 of the cantilever 108—and hence also the measuring tip 106—is made to approach the sample 102, 302. In other words, the repulsive force acting on the measuring tip 106 becomes ever smaller, the closer the measuring tip 106 is made to approach the sample 102. One could also say that the atomic force microscope 104 is used as a force sensor in the process, and that a force distance spectroscopy is performed.

In a fourth step S4′ of the method, at least one image 360 of the sample 302 is received, the test region 188 being at least partially captured therein (FIG. 11).

In a fifth step S5′ of the method, whether the sample 302 has been damaged in the test region 188 is ascertained on the basis of the at least one received image 360. By way of example, the test region 188 (i.e., a material 190 of the test region 188) was not damaged by the measuring tip 106 in FIG. 11.

In a sixth step S6′ of the method, a minimal z-deflection D₃ and/or a minimal z-distance A₃ of the approach curve 186 ascertained in step S3′ is ascertained as a safe z-deflection D₃, D_{S} of the free end 114 of the cantilever 108 or as a safe z-distance A₃, A_{S} of the base end 112 of the cantilever 108 from the sample 102 should the sample 302 be ascertained as being undamaged in the test region 188 in step S5′.

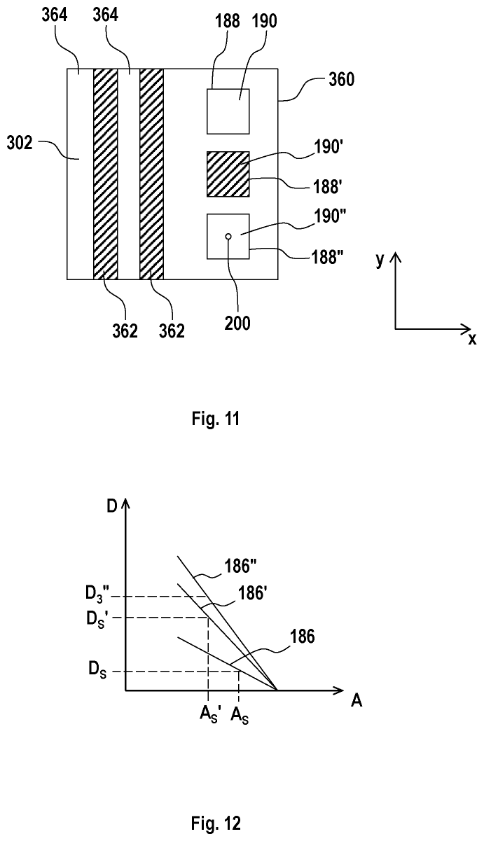

Optionally, a plurality of approach curves 186, 186′, 186″ (FIG. 12) are ascertained on the basis of in each case different test regions 188, 188′, 188″ (FIG. 11) in this method. The test regions 188, 188′, 188″ differ from one another, in particular by way of a type of a material 190, 190′, 190″ of the respective test region 188, 188′, 188″. Thereupon, at least one image 360 is recorded using an image recording device 128, the plurality of test regions 188, 188′, 188″ being at least partially captured therein. Also, at least one image 360 can be recorded for each test region 188, 188′, 188″. For each ascertained approach curve 186, 186′, 186″, there subsequently is an ascertainment as to whether the sample 302 is damaged in the respective test region 188, 188′, 188″ using the at least one received image 360 as a basis. In the example of FIG. 11, the respective material 190, 190′ of the test regions 188, 188′ was not damaged by the measuring tip 106. Merely by way of example, an impression 200 left by the measuring tip 106 is elucidated for the test region 188″ as an example of damage to the material 190″ of the test region 188″. By way of example, no damage to the sample 302 was consequently ascertained for the test regions 188, 188′. Furthermore, damage to the sample 302 was ascertained by way of example for the test region 188″. Next, a safe deflection D_{S}, D_{S}′ (FIG. 12) of the respective approach curve 186, 186′ is stored as a function of the corresponding material 190, 190′ of the respective test region 188, 188′ should the sample 302 be ascertained as being undamaged in the respective test region 188, 188′.

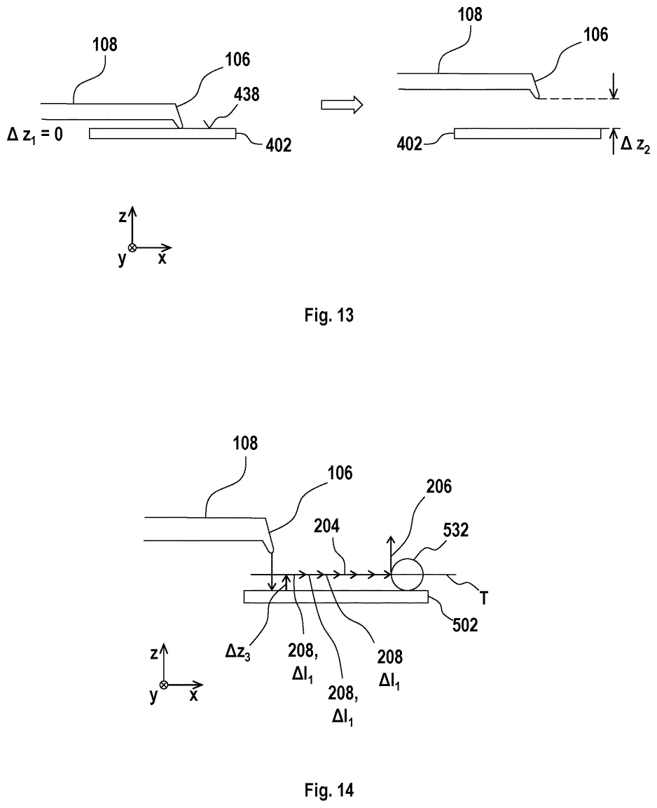

In the proposed method, the measuring tip 106 can optionally also be positioned automatically at a suitable predetermined working distance Δz₂ from the sample 402, as elucidated in FIG. 13. In particular, provision can be made for the positioning unit 110 to initially be controlled to move the measuring tip 106 in the negative z-direction such that the measuring tip 106 is brought into contact with the sample 102 (left-hand drawing in FIG. 13). Here, a distance Δz₁ between the measuring tip 106 and the sample 402 is equal to zero (Δz₁=0). Next, provision can be made for a predetermined working distance Δz₂ to be set between the measuring tip 106 and the sample 402 using the contact between the measuring tip 106 and the sample 402 as a starting point. To this end, the positioning unit 110 can be controlled to move the measuring tip 106 in the direction of the sample 402 and/or the further positioning unit 124 (FIG. 1) can be controlled to move the sample 402 arranged on the sample stage 120 in the direction of the measuring tip 106. In particular, the positioning unit 110 and/or the further positioning unit 124 is controlled in such a way that the measuring tip 106 and the sample 402 are brought to the predetermined distance Δz₂ from one another (right-hand drawing in FIG. 13).

As a result of setting the predetermined working distance Δz₂, image recordings (e.g., using the scanning electron microscope 128, FIG. 1) of the sample 402, the measuring tip 106 being at least partially captured therein, can be compared with one another in an improved fashion. Hence image-monitored processing process, such as manipulation processes with the aid of the measuring tip 106 (e.g., a displacement and/or removal of particles 132 on the sample 102, 402), for example, can be monitored better.

Optionally, a fully automatic iterative process for removing particles 532 can be provided in the proposed method, as illustrated in FIG. 14. This substantially simplifies the removal of particles 532.

In a first step S1″ of the iterative particle removal process, a removal trajectory T (e.g., a linear removal trajectory T) for removing a particle 532 arranged on the sample 502 is provided. In particular, the removal trajectory T lies in an xy-plane E (FIG. 3) that is spanned by the x- and the y-direction and intersects an xy-position (x_{P}, y_{P}; FIG. 3) of the particle 132, 532. For illustrative reasons, the particle 532 has been drawn excessively large relative to the measuring tip 106 in FIG. 14. However, in reality, the particle 532 in FIG. 14 (and in other figures) can be much smaller in relation to the measuring tip 106.

In a second step S2″ of the iterative particle removal process, the positioning unit 110 is fully automatically controlled to position the measuring tip 106 at a first predetermined z-distance Δz₃ (e.g., Δz₃=50 nm) from the sample 502 in relation to the z-direction.

In a third step S3″ of the iterative particle removal process, the positioning unit 110 is fully automatically controlled to laterally move 204 (i.e., in the x- and/or the y-direction) the measuring tip 106 along the ascertained removal trajectory T. In particular, in the process the measuring tip 106 is kept from the sample 502 at the first predetermined z-distance Δz₃ set in step S2″. In the example of FIG. 14, the movement of the measuring tip 103 in step S3″ is in the x-direction only. However, in other examples the movement of the measuring tip 103 in step S3″ can also be implemented in the x- and the y-direction or in the y-direction only.

Optionally, in method step S3″, the measuring tip 106 is moved incrementally in individual steps 208 of a predetermined lateral distance Δl₁ (e.g., Δl₁=20 nm). Method step S3″ can also be carried out multiple times for lateral distances Δl₁, Δl₂ that are different in each case, as elucidated in FIG. 15A. In this case, the lateral distances Δl₁, Δl₂ increase with increasing number of repetitions (e.g., Δl₁=20 nm and Δl₂=50 nm).

In a fourth step S4″ of the iterative particle removal process, the positioning unit 110 is fully automatically controlled to move 206 (FIG. 14) the measuring tip 106 away from the sample 502 in the positive z-direction.

In a fifth step S5″ of the iterative particle removal process, whether the particle 532 adheres to the measuring tip 106 is ascertained fully automatically.

In a sixth step S6″ of the iterative particle removal step, steps S2″ to S5″ are repeated fully automatically for one or more further predetermined z-distances Δz₄, Δz₅, Δz₆, Δz₇, as elucidated in FIG. 15B. The further predetermined z-distances Δz₄, Δz₅, Δz₆, Δz₇ are in particular progressively smaller than the first predetermined z-distance Δz₃ (e.g., Δz₄=40 nm, Δz₅=30 nm, Δz₆=20 nm, Δz₇=10 nm). In particular, steps S2″ to S5″ are fully automatically repeated for progressively smaller z-distances Δz₄, Δz₅, Δz₆, Δz₇ until the particle 532 is ascertained as adhering to the measuring tip 106.

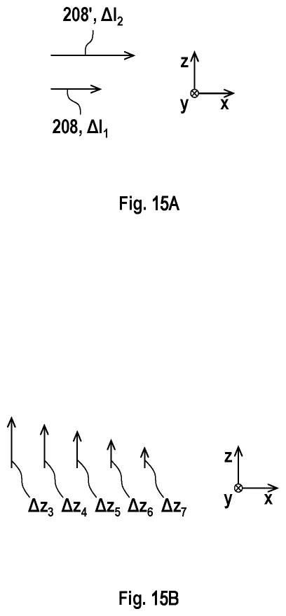

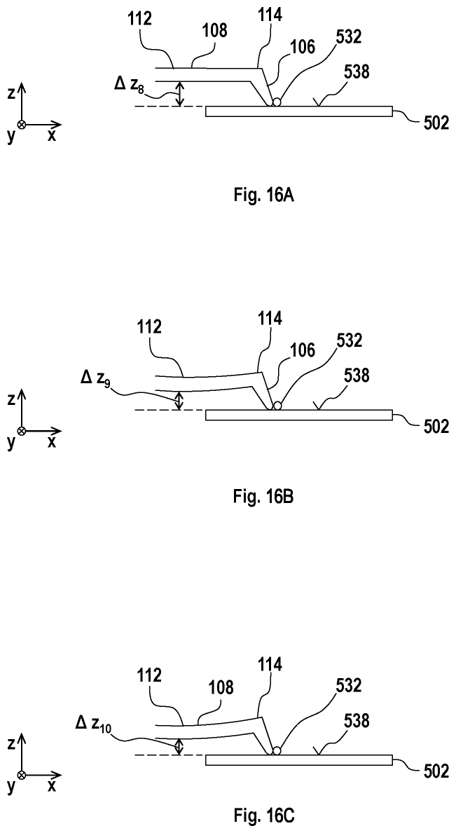

Optionally, a further fully automatic iterative process for removing particles 532 can be provided in the proposed method, as illustrated in FIGS. 16A to 16C.

In a first step of the method, the positioning unit 110 is controlled to position the measuring tip 106 on a surface 538 of the sample 502 and adjacent to a particle 532 on the surface 538 of the sample 502. In so doing, a base point 112 of the cantilever 108 is situated in relation to the z-direction at a first predetermined z-distance z₈ from the sample 502.

In the second step of the method, the positioning unit 110 is controlled to laterally move the measuring tip 106 (i.e., in the x- and/or y-direction) in order to detach the particle 532 from the surface 538.

Whether the particle 532 is or has moved on the surface 538 (i.e., changed its position on the surface 538 from an initial position in the first step) is ascertained in a third step of the method.

For example, the third step is performed with the aid of an image recording device 128 (FIG. 1). For example, an image which captures the particle 532 is recorded by the image recording device 128 in both the first step and the third step.

In a fourth step of the method, the first to third steps are repeated for one or more further predetermined z-distances z₉, z₁₀ (FIGS. 16B, 16C) between the base point 112 of the cantilever 108 and the sample 502. In particular, the further predetermined z-distances z₉, z₁₀ are progressively smaller than the first predetermined z-distance z₈. As a result, an incrementally increasing force is exerted on the measuring tip 106 and hence on the particle 532. As evident from FIGS. 16B and 16C, the cantilever 108 bends progressively in the process. The first to third steps are repeated for the one or more further predetermined z-distances z₉, z₁₀ between the base point 112 of the cantilever 108 and the sample 502 until the particle 532 on the surface 538 is ascertained as having moved.

In particular, the first to fourth steps are carried out fully automatically.

By repeating the steps of the method for progressively smaller z-distances z₈, z₉, z₁₀ between the base point 112 of the cantilever 108 and the sample 502, it is possible to apply to the measuring tip 106 only precisely the force required to detach the particle 532 from the surface 538, without causing damage to the measuring tip 106 and/or the sample 538.

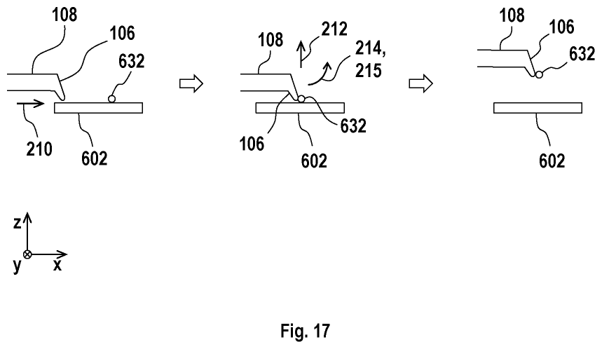

Optionally, a fully automatic move and lift process can be provided for the measuring tip 106 in the proposed method, as illustrated in FIG. 17. To this end, the positioning unit 110 is initially controlled to laterally move 210 (FIG. 17) the measuring tip 106 in the direction of a particle 632 arranged on the sample 602. Whether the particle 632 adheres to the measuring tip is ascertained next. The adherence of the particle 632 to the measuring tip 106 can be checked on the basis of various methods as described below. Should the particle 632 be ascertained as adhering to the measuring tip 106, the positioning unit 110 is controlled to perform a lift movement 212, 214 of the measuring tip 106. As evident in the center of FIG. 17, the lift movement 212, 214 can be a movement 212 of the measuring tip 106 in the positive z-direction only in a first variant. Furthermore, the lift movement 212, 214 can be a movement 214 of the measuring tip 106 along a curved trajectory 215 in a second variant, the said trajectory curving in the region of the particle 632 from an initially lateral movement into a movement in the positive z-direction.

Hence a move and lift process 210, 212, 214 of the measuring tip 106, as might be required to pick up a particle 632 from the sample surface, can be carried out fully automatically, including a check as to whether the particle 632 adheres to the measuring tip 106.

Optionally, a (e.g., fully automatic) check as to whether a particle 632 (FIG. 17) adheres to the measuring tip 106 might be provided in the proposed method. To this end, the positioning unit 110 (e.g., as shown in FIG. 14 and/or FIG. 17) is controlled to move the measuring tip 106 laterally and/or in the positive z-direction in order to pick up a particle 632 arranged on the sample 602 using the measuring tip 106. Thereupon, whether the particle 632 adheres to the measuring tip 106 is ascertained in accordance with one or more of the following four variants.

In the first variant, whether the particle 632 adheres to the measuring tip 106 is ascertained on the basis of an extent of a lateral deflection of the cantilever 108 (i.e., in the x- and/or y-direction), which is received from the deflection detection device 150 (FIG. 2).

For example, the lateral deflection of the cantilever 108 can be ascertained with the aid of the light pointer device 150. In particular, lateral forces acting between the measuring tip 106 and the sample 102 can cause a rotation R of the free end 114 of the cantilever 108 about the x-direction. Hence, the lateral deflection of the cantilever 108 can be ascertained with the aid of the light pointer device 150, for example, by detecting the extent of the rotation R of the free end 114 of the cantilever 108 about the x-direction.

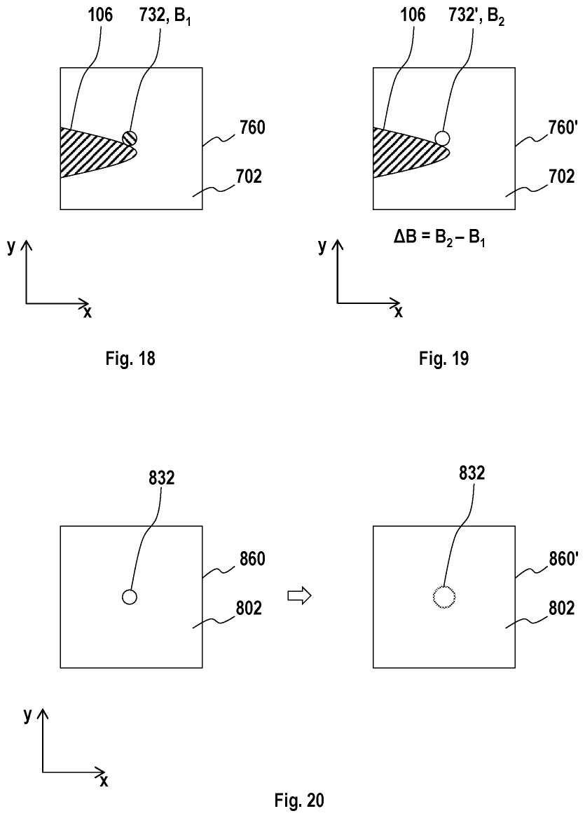

In the second variant, whether the particle 732, 732′ adheres to the measuring tip 106 is ascertained on the basis of a change in the brightness ΔB and/or a change in the contrast of the particle 732 in images 760, 760′ of the particle 732, 732′ (e.g., in electron microscope images and/or ion microscope images), as illustrated in FIGS. 18 and 19. At least one part of the measuring tip 106 is also captured in the plurality of received images 760, 760′ of the sample 702, in addition to the particle 732, 732′. The particle 732 does not yet adhere to the measuring tip 106 in the image 760 (FIG. 18). By contrast, a brightness B2 of the particle 732′ in the further image 760′ (FIG. 19) has increased significantly in comparison with a brightness B1 of the particle 732 in image 760 (i.e., the particle 732′ in image 760′ is brighter than the particle 732 in image 760). In particular, the change in brightness ΔB arises from the difference in the brightnesses B1 and B2. In other words, a contrast between the particle 732′ and the measuring tip 106 in FIG. 19 is greater than a contrast between the particle 732 and the measuring tip 106 in FIG. 18. This is an indication of electric charging of the particle 732′ in FIG. 19 on account of adhering, and hence of the particle 732′ adhering to the measuring tip 106 in FIG. 19.

In a third variant, the particle 832′ adhering to the measuring tip 106 is ascertained on the basis of a migration of the particle 832, 832′ out of a fixedly set focus of the image recording device 128, as illustrated in FIG. 20. This is because this is an indication of the particle 832′ being lifted together with the measuring tip 106. In particular, what is ascertained here on the basis of the images 860, 860′ is that the particle 832 initially (image 860, to the left in FIG. 20) is situated in a focus of the image recording device 128, and the particle 832′ is no longer situated in the focus of the image recording device 128 in later images 860′ (to the right in FIG. 20).

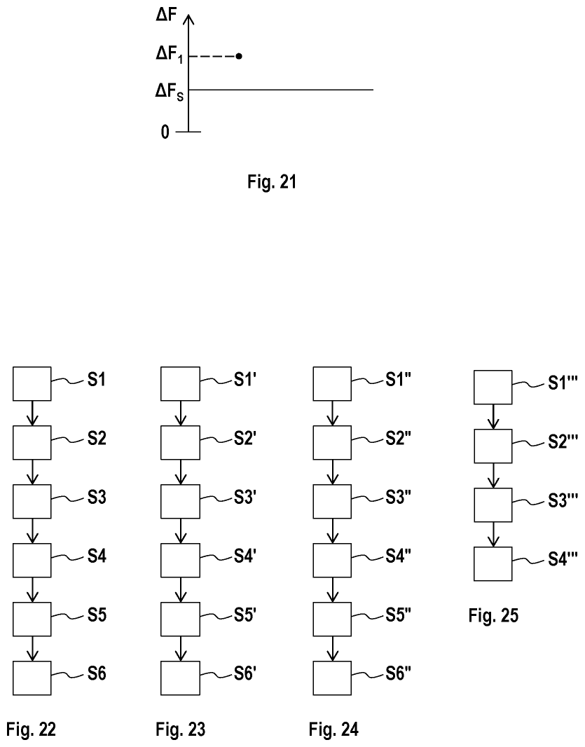

In the fourth variant, the images 160 (FIG. 3) of the particle 132 are recorded using the image recording device 128 with an autofocus setting that is focused on the particle 132. Furthermore, what follows from an automatic adjustment ΔF (FIG. 21) by more than the predetermined threshold value ΔF_{S} of the autofocus focused on the particle 132 is that a z-position Pz of the particle 132 has changed significantly, and this indicates a lifting of the particle 132 together with the measuring tip 106 (in the positive z-direction). FIG. 21 illustrates a change ΔF in the autofocus. An automatic adjustment ΔF₁ which is greater than the threshold value ΔF_{S} can, for example, be interpreted as an indication for a movement of the particle 132 in a manner corresponding to an adhering to the measuring tip 106.

Optionally, a fully automatic centration of the measuring tip 106 and sample stage 120 can be provided in the proposed method. In particular, the atomic force microscope 104 comprises the sample stage device 126 having the mount 122, the sample stage 120 arranged on the mount 122 so as to be laterally movable and the further positioning unit 124 for laterally moving the sample stage 120 relative to the mount 120 in the x- and the y-direction. The sample stage 120 can, for example, also be mounted rotatably on the mount 122, such that it can be rotated about the x-, y- and/or z-direction with the aid of the further positioning unit 124.

In a first step S1′″ of the method, the positioning unit 110 is controlled to fully automatically position the measuring tip 106 in an initial position Px₀, Py₀ (e.g., at x=0 and y=0), preset in the positioning unit 110, in relation to the x- and the y-direction.

In a second step S2′″ of the method, at least one image 160 of the sample 102 in which a particle 132 arranged on the sample 102 is captured is recorded.

In a third step S3′″ of the method, a lateral position x_{P}, y_{P} (FIG. 3) of the particle 132 captured in the at least one image 160 is ascertained by use of image processing.

In a fourth step S4′″ of the method, the further positioning unit 124 is controlled to laterally move the sample stage 120 relative to the mount 122, in such a way that the lateral position x_{P}, y_{P} of the particle 132 corresponds to the initial position Px₀, Py₀ of the measuring tip 106 in relation to the x- and the y-direction.

Using the described methods, the x-, y- and/or z-positions of the apex 168 of the measuring tip 106 can be ascertained more accurately, and so the sample 102 can be processed more precisely using the measuring tip 106. Moreover, the required nanometer-scale manipulations with the measuring tip 106 can be facilitated and/or automated in various ways.

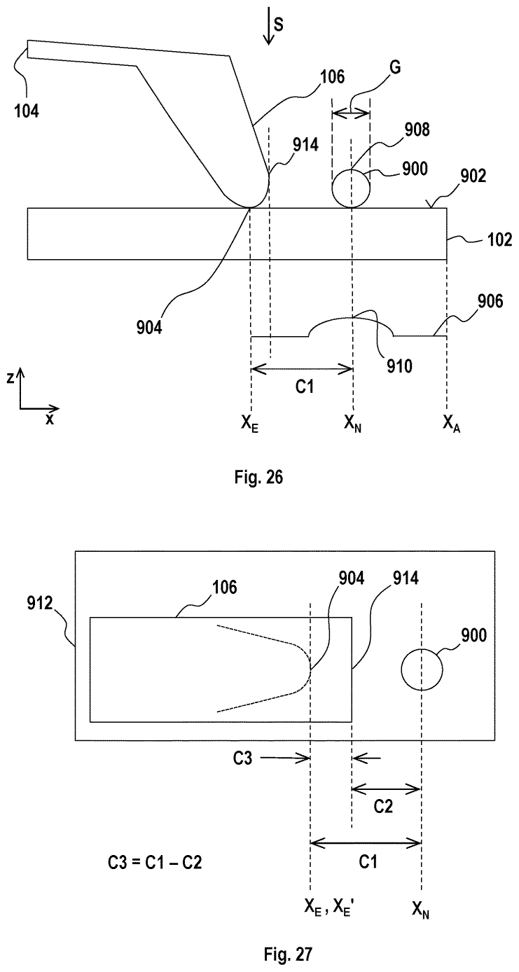

FIGS. 26 to 28 illustrate a further computer-implemented method for processing a sample 102 using a nanomanipulator 104 (FIG. 1). The nanomanipulator 104 comprises a measuring tip 106 for processing the sample 102 and a positioning unit 124 for moving the measuring tip 106. Only the measuring tip 106 of the nanomanipulator 104 is visible in FIG. 26; with regards to other components of the nanomanipulator 104, for example, the positioning unit 124, a sample stage 120 on which the sample 102 is arranged and an image recording unit 128, reference is made to FIG. 1 and the description thereof. An x-direction and a y-direction of the nanomanipulator 104 are each arranged parallel to a main extension plane E of the sample 102 and/or sample stage 120 and perpendicular to one another. The sample 120 has a nanostructure 900 on its surface 902 for the purpose of ascertaining an actual apex 904 of the measuring tip 106.

In a first step S1″″ of the method, the positioning unit 124 is controlled to laterally (in the x- and/or y-direction) move the measuring tip 106 from lateral initial coordinates x_{A} to lateral end coordinates x_{E} in order to scan the nanostructure 900. Raster-scan data 906 are created in the process.

By way of example and for illustrative reasons, a respective x-coordinate is specified as lateral initial coordinate x_{A} and as lateral end coordinate x_{E} in FIG. 26. However, the lateral initial coordinates and lateral end coordinates can each have an x- and/or y-coordinate as positional specification.

In a second step S2″″ of the method, nanostructure coordinates x_{N} of a highest point 908, 910 of the nanostructure 900 are ascertained in the raster-scan data 906.

In FIG. 26, an x-coordinate is also specified as nanostructure coordinate x_{N}. However, the nanostructure coordinate x_{N} might also have an x- and/or y-coordinate as positional specification.

In the third step S3″″ of the method, a first lateral distance C1 is ascertained between the nanostructure coordinates x_{N} and the lateral end coordinates x_{E}.

In a fourth step S4″″ of the method, at least one image 912 (FIG. 27) of the sample 102 is recorded, the measuring tip 106 and the nanostructure 900 being at least partially captured therein. In this case, an actual apex 904 (which is not visible in the image 912) of the measuring tip 106 is situated at the lateral end coordinates x_{E}. An apparent apex 914 of the measuring tip 106 which is visible in the image 912 is also shown in FIG. 27.

In a fifth step S5″″ of the method, a second distance C2 is ascertained in the image 912 (e.g., by image analysis) between the apparent apex 914 of the measuring tip 106 and the nanostructure 900 (e.g., the nanostructure coordinate x_{N}).

In a sixth step S6″″ of the method, a lateral position x_{E}, x′_{E} of the actual apex 904 of the measuring tip 106 is ascertained on the basis of a difference between the first and second distance C1, C2. For example, a third distance C3 is ascertained between the apparent apex 914 and the actual apex 904 of the measuring tip 106 by virtue of the second distance C2 being subtracted from the first distance C1.

A position x_{E}, x′_{E} of the actual apex 904 of the measuring tip 106, which is not visible in the image 912, can nevertheless be ascertained in this way.

The nanostructure 900 for ascertaining the actual apex 904 of the measuring tip 106, for example, has a lateral dimension G (FIG. 26) of 30 nm or less, 20 nm or less, 10 nm or less and/or 5 nm or less.

In the example of FIGS. 26, 27, the nanostructure 900 for ascertaining the actual apex 904 of the measuring tip 106 has a spherical shape and/or a spherical surface.

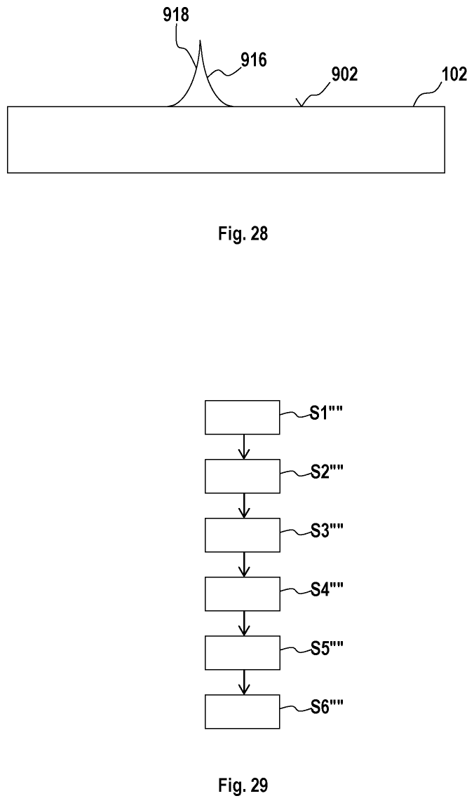

As shown in FIG. 28, however, a nanostructure 916 for ascertaining the actual apex 904 of the measuring tip 106 might also, for example, have a tip 918, which for example, tapers in a direction going away from the sample surface 902.

According to a further embodiment, systems, apparatuses and methods for landing a probe of a nanomanipulator 104 on a sample 102 are provided and described below. The apparatus may be similar to the apparatuses described above with respect to FIGS. 1 and 2. Accordingly, components and details described above may also be present in or applicable to the systems described below, unless stated differently. The disclosed method may be implemented at least in part on a computing system, for example, the control apparatus 140 described above.

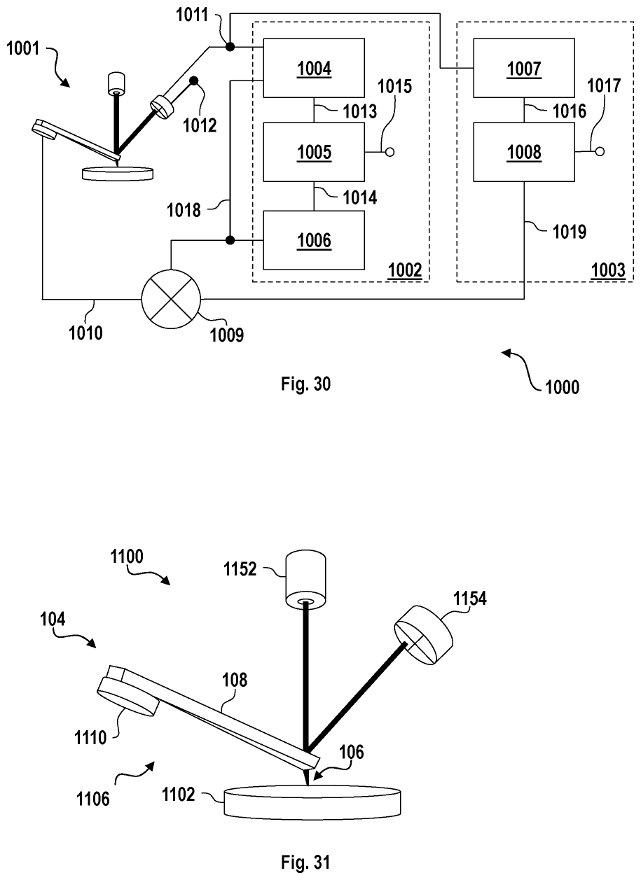

FIG. 30 shows a schematic diagram of a system 1000 for detecting a frequency shift of a driving signal. The system 1000 comprises a cantilever deflection system 1001 (e.g., a beam deflection system 1100 as described below), a frequency control system 1002, and an amplitude control system 1003. The frequency control system 1002 comprises a phase detector 1004, a first feedback unit 1005 (e.g., an integrator), and a controllable oscillator 1006 (e.g., a voltage controlled oscillator or numerically controlled oscillator). The amplitude control system 1003 comprises an amplitude detector 1007 (e.g., a root mean square detector), and a second feedback unit 1008 (e.g., a proportional-integral (PI) controller). A first output signal provided by the frequency control system 1002, and a second output signal provided by the amplitude control system 1003 are combined by a multiplier 1009 to provide a driving signal to an excitation unit of the cantilever deflection system 1001 (i.e., an excitation signal, such as A sin(2πf t), where A is the second output signal corresponding to the amplitude provided by the amplitude control system 1003, and sin(2πf t) is the first output signal provided by frequency control system 1002, wherein f is the current operating frequency of the controllable oscillator 1006 and t is the time). The excitation unit 1110 may comprise an excitation piezo as shown in FIG. 31 or a similar actuator converting the electrical driving signal into a mechanical vibration, thereby leading to a forced oscillation of a cantilever 108 attached thereto. The oscillation of the cantilever 108 or other parts of the probe attached thereto may be detected as deflection signal 1011 by a 4-quadrant photodiode 1154 as shown in FIG. 31 or a similar sensor converting the mechanical oscillation back into an electrical control signal. Note that the 4-Quadrant photodiode 1154 may also provide a lateral signal 1012. However, the lateral signal is not necessary for implementing the control loop described below.

The frequency control system 1002 follows a phase component of the deflection signal 1011 by forming a phase locked loop (PLL). In particular, the phase detector 1004 compares the deflection signal 1011 with a current oscillator output signal 1018 to output a corresponding phase signal 1013, e.g., a phase error signal. The first feedback unit 1005 integrates the phase signal 1013 to provide a frequency control signal 1014 indicative of a frequency shift (i.e., frequency shift dF) based on the integrated phase signal 1013 and a phase setpoint 1015. In resonant driving conditions, the phase angle between the excitation signal 1010 and the deflection signal 1011 should be close to 90°. However, due to delays in the processing circuitry or other imperfections, the phase setpoint may be set to a value above or below 90° as detailed further below with regard to the determination of resonance characteristics. The frequency control signal 1014 is fed to the controllable oscillator 1006 to adjust a frequency of the oscillator output signal 1018 provided by the oscillator 1006 to follow the resonance frequency of the cantilever.

The amplitude control system 1003 provides an amplitude control loop. In particular, the amplitude detector 1007 detects a current signal strength of the deflection signal 1011 and provides a corresponding amplitude signal 1016 to the second feedback unit 1008. Based on the amplitude signal 1016 and an amplitude setpoint 1017, the second feedback unit 1008 provides an amplitude feedback signal 1018 for maintaining an amplitude of the cantilever's maximum deflection close to a desired value.

FIG. 31 shows a schematic diagram of an exemplary configuration of a beam deflection system 1100 (e.g., the cantilever deflection system 1001 of the system 1000). As shown, a tip 106 (e.g., a measurement tip or a manipulation tip) is attached to a cantilever 108. Together, the tip 106 and the cantilever 108 form a probe 1106 for detecting or manipulation a specimen 1102 (e.g., a sample 106). The probe 1106 can be mechanically driven (e.g., excited) by an excitation unit 1110. For example, a first end of the cantilever 108 (i.e., the end 112 in FIGS. 1 and 2) may be attached to the piezo 1110, whereas the tip 106 may be attached to a second (e.g., opposite) end of the cantilever 108 (i.e., the end 114 in FIGS. 1 and 2). Light from a light source 1152, e.g., a LED or laser diode, is reflected of the second end towards a 4-quadrant photodiode 1154 to detect a deflection of the cantilever. Note that the use of a 4-quadrant photodiode 1154 allows the generation of different control signals. In particular, a first deflection signal in a z-direction, i.e., a vertical deflection value DFL, and a lateral deflection of the cantilever in the x/y direction, i.e., a lateral deflection value LAT may be determined. The lateral deflection value LAT is computed as the sum of the left two diode areas minus the sum of the right two diode areas. Similarly, the vertical deflection value DFL is computed as the sum of the upper two diode areas minus the sum of the lower two diode areas. In addition, a sum signal SUM over all four diode areas may be provided.

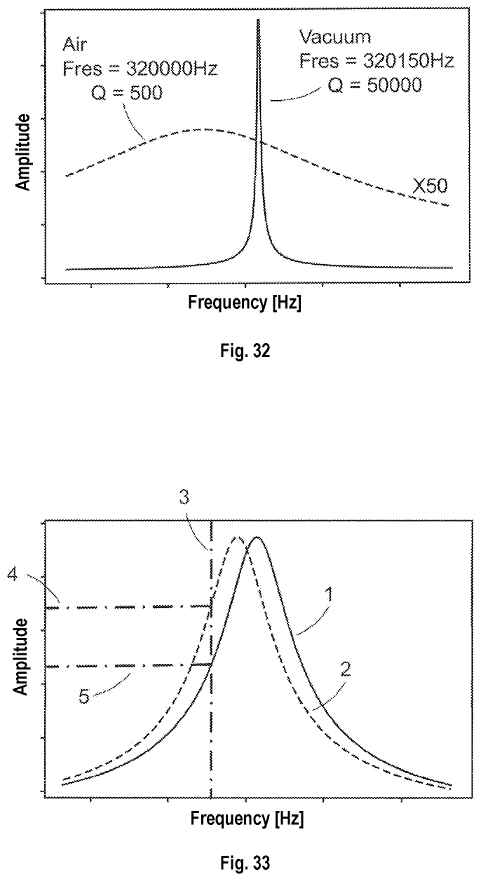

FIG. 32 shows resonance curves of a probe 1106 in vacuum and air, respectively. Note that the two curves differ significantly in that the peak in vacuum is much narrower and higher than the peak of the same probe 1106 oscillating in air (shown at a magnification factor of 50× to present it in the same diagram). One of the reasons for this behavior is that the air has a damping effect on the oscillation. This results in a much lower Q-value of 500 instead as 50,000 as well as a downwards shift of the resonance frequency from about 320,150 Hz to 320,000 Hz for the example probe 1106. Further note that due to the higher damping in air, an amplitude of the oscillation of the probe 1106 in air changes more quickly than the amplitude of the oscillation of the probe 1106 in vacuum (e.g., at a pressure at or below 10e⁻³ mbar).

FIG. 33 illustrates a first method for detecting an interaction between a probe 1106 and a sample based on tracking an amplitude signal. The method shown in FIG. 33 is based on detecting changes in an amplitude of an oscillation, and may therefore be referred to as AM (amplitude modulation) detection for short.

In the AM detection, the cantilever 108 is excited with a fixed amplitude and a fixed frequency signal and a constant (controlled) amplitude. Curve 2 of FIG. 33 shows the resonance curve without tip—sample interaction. In contrast, Curve 1 shows a resonance curve with repulsive tip—sample interaction to the right of curve 2, i.e., at a higher resonance frequency. In AM detection, the measured amplitude signal is used as input for the topography feedback. Line 4 shows the oscillation amplitude without tip—sample interaction. In contrast, line 5 shows the oscillation amplitude with repulsive tip sample interaction. The amplitude change due to tip—sample interaction always reduces the observed amplitude as the resonance frequency rises. Accordingly, an operating point for the excitation signal is selected away from the resonance frequency as shown by line 3 of FIG. 33.

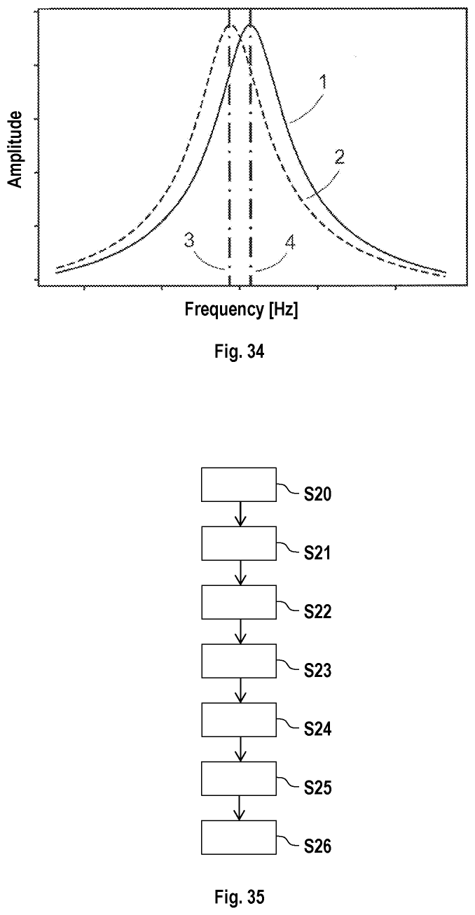

FIG. 34 illustrates a second method for detecting an interaction between a probe 1106 and a sample based on tracking a frequency signal, according to a further embodiment of the present disclosure. The method shown in FIG. 34 is based on detecting changes directly in a frequency of an oscillation, and may therefore be referred to as FM (frequency modulation) detection for short.

Contrary to the AM detection method, in the FM detection method the oscillator, i.e., the cantilever 108 and/or other parts of a probe 1106 are driven (i.e., excited) at their resonance frequency. This may be implemented, as detailed above, using a PLL or similar frequency control circuit (e.g., 1002 above). In addition, an amplitude feedback circuit (e.g., 1003 above) may be used to control an amplitude of the oscillation to stay constant. Curve 1 of FIG. 34 shows a first resonance curve with repulsive tip—sample interaction. Curve 2 shows a second resonance curve without tip—sample interaction. As before, the resonance frequency is shifted upwards when the tip 106 of the probe 1106 approaches the sample 102. In the FM detection method, a frequency shift signal dF is used as input signal for the topography feedback. This signal may be provided by a PLL or similar frequency control circuit as described above. Note that the use of a PLL provides a very fast response signal to variations in a resonance frequency and thus allows a better response to tip—sample interactions, in particular in vacuum or at reduced atmospheric pressure.

FIG. 35 shows a flowchart of a, partially or fully computer-implemented, method for landing a probe 1106 of a nanomanipulator on a sample using the system from FIG. 30 and the FM detection method described above, according to one embodiment.

In a step S20, resonance characteristics of a probe 1106 are measured. This is performed in a state where the tip 106 is not in contact with or proximate to the probe. For example, the tip may be located at a significant distance from the probe 1106, i.e., at a distance between 50 to 500 μm, for example 100 μm, where forces (e.g., attractive or repulsive forces) acting between the tip 106 and the sample 102 are negligible. For example, a frequency sweep signal may be used to determine a resonance frequency (i.e., a natural or harmonic frequency) of the probe 1106. In addition, other parameters, including a Q-value and a phase setpoint value corresponding to a phase difference between the excitation signal and the deflection signal specific for the system 1000 may be determined. Alternatively, part or all of a characteristic of the probe 1106 may be provided as stored values, e.g., by a manufacturer or from a library, etc.

The actual landing of the probe 1106, i.e., the approach of the tip 106 to a surface of the sample 102, may be performed in several stages and/or using corresponding operation modes.

During a first stage or approach phase, the above FM detection may be employed to avoid an unwanted hard contact between the tip 106 and the probe 1106. The FM detection mode provides a high sensitivity for the detection of attractive or repulsive forces. During this stage, small electrostatic, attractive forces can be detected and analyzed. If the electrostatic force exceeds a predefined threshold, the approach may be aborted to avoid damaging the probe 1106.

This operating mode may be referred to as dynamic mode of the system. In the dynamic mode, the probe 1106 is actively driven and oscillates mechanically. In other words, in the dynamic mode, the excitation signal 1010 is provided to the excitation unit 1110. In the dynamic mode, multiple parameters may be monitored and used to determine an approach of the tip 106 to the surface of the sample 102 and/or various error conditions that may be encountered. As the system 1000, including the cantilever deflection system 1001 and the frequency control system 1002, forms a control loop for tracking the resonance frequency of the probe, this mode may also be referred to as closed loop operation, and some or all of the control signals provided by the frequency control system 1002 and the amplitude control system 1003 may be used to monitor and/or control the first approach phase (e.g., an initial phase of the landing operation). For example, in the dynamic mode, the amplitude feedback signal 1019, the phase signal 1013 and the frequency control signal 1014 derived during closed loop control from the deflection signal 1011 may be monitored and analyzed. In addition, further system parameters, including open loop parameters, like the SUM, LAT and DFL signals provided by the sensor 1154, may also be monitored and analyzed. A vertical speed of the tip 106 may also be monitored. For example, the speed of a fine drive of a positioning unit may be monitored.

In a step S21, a resonant driving signal is provided to the excitation unit 1110. Initially, the piezo exciter may be driven with a known, natural resonance frequency of the probe 1106 determined, for example, in step S20. Once the oscillation is started, it is maintained by the control loop(s) of the system 1000 while tracking the resonance frequency of the probe 1106. In addition, at least one of the above parameters is selected to define a stop condition for the first stage of the approach. For example, an approach is halted when the difference frequency or frequency shift dF (e.g., frequency control signal 1014) exceeds an upper frequency threshold indicative of a tip—probe interaction corresponding to a repulsive force. Alternatively or in addition, the approach may also be halted when the amplitude of the oscillation falls below a lower amplitude indicating that the oscillation is partly blocked by the sample, i.e., parts of the probe 1106 are in contact with the sample. An unusually large amplitude, unusually small or large phase signal values or a negative difference frequency dF may be indicative of various error conditions, such as an uncontrolled oscillation of the cantilever, a loss of locking by the PLL or a high electrostatic charge of the probe 1106 and/or sample.

In step S22, a first approach phase is performed. In the following, a control of the probe 1106 by use of a coarse and a fine drive of the positioning unit 110 is used as example for simplicity. However, in other embodiments, all or part of the relative movement may be affected by moving the sample stage 120 and or by a single-stage positioning unit 110 for moving the probe 1106. For example, a coarse and/or fine drive of the positioning unit 110 may be used concurrently or intermittently to reduce the distance in the z-direction between the tip 106 and the sample 102. As a specific example, the tip 106 may be advanced by the fine drive first. Then, if the sample is not detected within the range of the fine drive, the fine drive is returned to a minimal position, and the coarse drive is advanced by a corresponding amount. The approach continues until one of the stop criteria is met. Assuming that no error conditions are encountered, the approach should stop when a repulsive force starts to act between the tip 106 and the sample 102, resulting in a noticeable upwards shift of the resonance frequency, i.e., a dF value exceeding a predefined threshold. The tip 106 is now in proximity to the surface of the sample 102.

Optionally, in a step S23, this z-position is saved. Alternatively, the tip 106 may be retracted by a small, predefined amount to avoid an unintended contact. For example, the control unit may retract the tip by a fixed distance, such as one or several nanometers, or by a number of steps of a digital control parameter Zfine used for control of the fine drive.

Optionally, to remove a particle 132 from a surface 138 of the sample 102 or perform other manipulations of the sample 102 or its surface 138, the system is switched into a second operating mode, referred to as static mode in the following. In the static mode, the tip 106 may approach the sample 102 even further in a second approach stage or phase, as described below.

In the static mode, the probe 1106 is not actively driven. Accordingly, deflection of the cantilever is determined by attractive and repulsive forces between the probe 1106 and the specimen 1102. In other words, in the static mode, no excitation signal is provided to the excitation unit 1110. Similar to the above, in the static mode, multiple parameters may be monitored and used to determine an approach of the tip to the surface of the sample 102 and/or various error conditions that may be encountered. As the control loop for tracking the resonance frequency of the probe is opened (i.e., deactivated), this mode may also be referred to as open loop operation, and only the remaining system parameters, including open loop parameters, like the SUM, LAT and DFL signals provided by the sensor 1154, may also be monitored and analyzed. A vertical speed of the tip 106 may also be monitored. For example, the speed of a fine drive of a positioning unit may be monitored.

In a step S24, the driving signal for the probe 1106 is deactivated to stop the oscillation of the cantilever 108. In addition, a different set of stop conditions is selected to control the further approach. Note that the tip 106 is already close to the surface 138 of the sample 102 at this stage. Thus, a parameter indicative of a direct contact between the tip 106 and the particle 132 or the surface 138 of the sample 102 may be used to stop the further approach. For example, a deflection signal, such as the vertical deflection signal DFL, of the cantilever 108 may be used directly as a stop condition the further approach. In addition, an unexpected low or high speed of the positioning unit 110 may be used as a stop condition or to indicate an error as described above.

In a step S25, the further approach is performed. For example, a further approach may be implemented by activating the fine drive to approach the sample surface step by step. Depending on the first stop criteria used in the first approach phase, the coarse drive may also be used. The approach is stopped when at least one of the second stop criteria is met. For example, the further approach may be stopped when the tip 106 is physically in touch with the surface of the sample 102 or a particle 132 located on the surface 138,

In a further, optional step S26, the position of the probe 1106 with respect to the sample 102 may be optimized in case a combination of a coarse and fine drive is used to control the approach. In this case, in order to provide a good dynamic range for the fine drive during particle or surface manipulation, a z-position of the contact position may be stored. Then, the tip 106 may be retracted by use of the fine drive. For example, the fine drive may be pulled completely away from the surface. Thereafter, the coarse drive may be controlled such that the contact position lies within the effective operating range of the fine drive. For example, the coarse drive may be moved away from or towards the surface until the stored contact position lies halfway between in minimum and a maximum range of the fine drive. In this state, the fine drive is once more used to bring the tip 106 back to the contact position. Optionally, a small negative or positive offset may be used to increase or reduce the final distance between the tip 106 and the surface. Alternatively or in addition, the same stop criteria may be used at this stage to prevent unwanted contacts with particles or the like.

The above procedure allows a fully or at least partially automatic landing of the tip 106 on the sample surface 138 or a particle 132 previously identified, accelerating a preparatory phase for manipulation of the surface 138 or the particle 132. It thereby greatly simplifies the approach maneuver conventionally performed under the operator's control. At the same time, it provides a high degree of safety due to the monitoring of relevant stopping criteria in real-time, thereby avoiding unwanted hard contacts between the tip 106 and the sample 102.

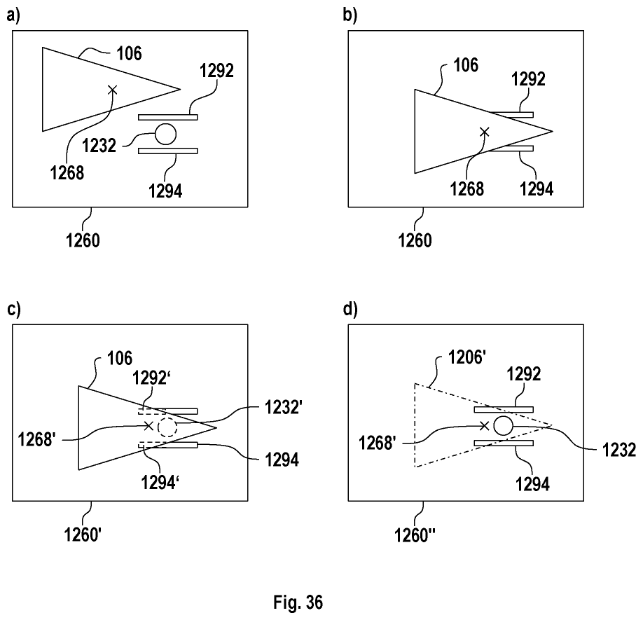

FIG. 36 shows different images provided by an apparatus for aiding a user during particle removal according to another embodiment.

As detailed above, image recording may be provided by a scanning electron microscope 128 or similar imaging device. In the described embodiment, image recording may be provided live, i.e., in real-time while the nanomanipulator 104 is active. This generally provides good control and feedback for the operator, e.g., during particle removal.

However, in case of manipulating very small surface structures of a sample 102 or during removal of very small particles 1232, the tip 106 may obscure the vision of the operator. This is depicted in the images 1260 provided by a scanning electron microscope according to FIGS. 36a) and b). Note that the structure features 1292 and 1294, for example line features, as well as a particle 1232 located on a surface of the sample 102 are smaller in width or diameter than the tip 106. Moreover, as detailed above, an actual contact point 1268 (i.e., actual apex 168) of the tip 106 may not lie at its outer edge (e.g., the left point in FIG. 36), but somewhere underneath the tip 106. That is to say, the operator may not be able to see the part of the surface 138 actually in contact with the tip 106. Moreover, when the operator moves the tip 106 to remove the particle 1232, the particle 1232 itself may be partially or fully obscured by the tip 106 as shown in FIG. 36b).

In order to provide the operator with better control during manipulation, an improved image 1260′ may be displayed on a user interface (e.g., human-machine interface 142).

In one embodiment, a first mark 1268′ is shown at the position of the contact point 1268 previously determined, for example, using the method for ascertaining the apex 168 described above. When the tip 106 is moved within the field of view corresponding to the image 1260, the position of the first mark 1268′ is moved in a corresponding direction to always mark the contact point 1268 as shown in FIGS. 36a) to d).

In the same or another embodiment, an edge detection, contrast analysis or similar image processing algorithm may be used to detect the outer edge (i.e., contours) or shape (i.e., area) of the structures features 1292, 1294 and/or particles 1232 before the tip 106 is moved over them, i.e., before the tip 106 obscures the structures features 1292 and 1294 and/or particles 1232. Then, when the tip 106 is moved over the structures features 1292 and 1294 and/or particles 1232, their previously detected edges or contours are indicated with special marks 1232′ and 1292′, and 1294′ as shown in FIG. 36c). Alternatively, an image of the entire surface may be stored (e.g., buffered) and may be used to show the entire surface physically obscured by the tip 106 as shown in FIG. 36d) by merging a segment of a stored image taken before the tip moved over the corresponding segment with a live image. In that case, the position of the tip 106 (i.e., the area comprising the image overlay) may be shown by a third mark 1206′ as also shown in FIG. 36d). Optionally, the user may choose between the output image 1260′ according to FIG. 36c) or the output image 1260″ according to FIG. 36d).

Although the present invention has been described on the basis of exemplary embodiments, it can be modified in various ways.

### LIST OF REFERENCE SIGNS

100 Apparatus
102 Sample
104 Nanomanipulator (atomic force microscope)
106 Measuring tip
108 Cantilever
110 Positioning unit
112 End
114 End
116 Housing
118 Pump
120 Sample stage
122 Holder
124 Positioning unit
126 Sample stage device
128 Particle column
130 Particle beam
132 Defect (particle)
134 Process gas providing unit
136 Process gas
138 Surface
140 Control apparatus
142 Human-machine interface
144 Display device
146 Keyboard
148 Mouse pointer
150 Deflection detection device
152 Laser source
154 Photodetector
156 Laser beam
158 Laser beam
160 Image
162 Structure
164 Trench
166 Substrate
168 Actual apex
170 Apparent apex
172 Surface
174 Surface
176 Region
178 Track
180 Straight line
182 Track
184 Straight line
186, 186′, 186″ Approach curve
188, 188′, 188″ Region
190, 190′, 190″ Material
200 Impression
204 Movement
206 Movement
208, 208′ Step
210 Movement
212 Movement
214 Movement
215 Trajectory
260, 260′, 260″ Image
302 Sample
360 Image
362 Structures
364 Trenches
402 Sample
438 Surface
502 Sample
532 Particle
538 Surface
602 Sample
632 Particle
702 Sample
732, 732′ Particle
760, 760′ Image
802 Particle
832, 832′ Particle
860, 860′ Image
900 Nanostructure
902 Surface
904 Actual apex
906 Raster-scan data
908 Point
910 Point
912 Image
914 Apparent apex
916 Nanostructure
918 Tip
1000 System
1001 Cantilever deflection system
1002 Frequency control system
1003 Amplitude control system
1004 Phase detector
1005 First feedback unit
1006 Controllable oscillator
1007 Amplitude detector
1008 Second feedback unit
1009 Multiplier
1010 Excitation signal (resonant driving signal)
1011 Deflection Signal
1012 Lateral signal
1013 Phase signal
1014 Frequency control signal (frequency shift signal)
1015 Phase setpoint
1016 Amplitude signal
1017 Amplitude setpoint
1018 Oscillator output signal
1019 Amplitude feedback signal
1100 Beam deflection system
1102 Specimen
1106 Probe
1110 Excitation unit (piezo)
1152 Light source
1154 Photodiode
1206′ Mark (tip indicator)
1232 Particle
1232′ Mark (particle indicator)
1260 Image
1260′, 1260″ Image
1268 Contact point
1268′ Mark (contact point indicator)
1292, 1294 Structure feature
1292′, 1294′ Mark (structure indicator)

A, A₁, A₂, A₃ Distance

A_{S}, A_{S}′ Distance
bl Region
br Region
B Bending
B1, B2 Brightness
C1, C2, C3 Distance
D Deflection
D₁, D₂, D₃, D₃″ Deflection
D_{S}, D_{S}′ Deflection
ΔB Change in the brightness
ΔF, ΔF₁ Change in the focus
ΔF_{S} Threshold value
Δl₁, Δl₂ Distance
Δx Distance, offset
Δy Offset
Δz₁-Δz₉ Distance
E Plane
G Dimension
H Height
Px, Py, Pz Position
Px₀, Py₀ Position
R Rotation
S Line-of-sight
S1-S6 Method steps
S1′-S6′ Method steps
S1″-S6″ Method steps
S1′″-S4′″ Method steps
S1″″-S6″″ Method steps
T Removal trajectory
ul Region
ur Region
x, y, z Direction
x1, x2 Position
x1′, x2′ Position
x_{A}, x_{E}, x′_{E} Position
x_{G} Position
x_{N} Position
x_{P} Position
y1, y2 Position
y1′, y2′ Position
y_{G} Position
y_{P} Position

1. A method for landing a tip of a probe of a nanomanipulator on a sample, in particular in vacuum, the probe comprising a cantilever and the tip attached thereto, the nanomanipulator further comprising an excitation unit, the probe being mechanically coupled with the excitation unit, the method including the following steps:
oscillating the probe by providing a resonant driving signal to the excitation unit while the tip is not in contact with the sample;
reducing a first distance in a z-direction between the tip and the sample during a first approach phase until at least one first stop condition of a first set of stop conditions is met, wherein the first set of stop conditions comprises detecting a shift in the frequency of the resonant driving signal used during the first approach phase; and
terminating the first approach phase when the at least one first stop condition of the first set of stop conditions is met, and deactivating the resonant driving signal.

2. The method according to claim 1, further comprising:
further reducing the first distance during a second approach phase until at least one second stop condition of a second set of stop conditions is met, wherein the second set of stop conditions comprises detecting a deflection of the cantilever; and
terminating the second approach phase at a contact position when the at least one second stop condition of the second set of stop conditions is met.

3. The method according to claim 2, wherein the location of at least one of the probe or the sample are controlled in the z-direction using a combination of a coarse drive and a fine drive, the method further comprising performing a third approach phase, comprising:
increasing the first distance by operating the fine drive to move the tip from the contact position to a partially retracted position; and
reducing or increasing the first distance by operating the coarse drive based on a second distance in the z-direction between the contact position and the partially retracted position; and
reducing the first distance by operating the fine drive to return the tip to the contact position or to a predefined position at third distance in the z-direction from the contact position.

4. The method according to claim 1, further comprising:
determining at least one parameter of a resonance characteristic of the probe while the tip is not in contact with the sample, the at least one parameter comprising at least one of a resonance frequency of the probe, a Q-value of the probe, or a phase angle between the resonant driving signal and a detected deflection signal associated with the oscillation of the probe.

5. The method according to claim 1, wherein the first set of stop conditions comprises at least one of the following conditions:
a frequency control signal indicative of shift in the frequency of the resonant driving signal exceeding a first threshold value;
a frequency control signal indicative of shift in the frequency of the resonant driving signal lying below a second threshold value;
an amplitude feedback signal used for amplitude control of the resonant driving signal exceeding a third threshold value;
an amplitude feedback signal used for amplitude control of the resonant driving signal lying below a fourth threshold value;
a phase signal indicative of a relationship between the resonant driving signal and a detected oscillation of the probe exceeding a fifth threshold value and/or lying below a sixth threshold value; and/or
a driving speed in the z-direction exceeding a seventh threshold value and/or lying below an eighth threshold value.

6. The method according to claim 5, wherein landing the probe is aborted in the first approach phase when at least one of the following conditions are met:
the frequency control signal lies below the second threshold value;
the amplitude feedback signal exceeds the third threshold value;
the phase signal exceeds the fifth threshold value and/or lies below the sixth threshold value; and/or
the driving speed exceeds the seventh threshold value and/or lies below the eighth threshold value.

7. The method according to claim 2, wherein the second set of stop conditions further comprises:
a first deflection signal indicative of a deflection of the probe in the z-direction exceeding a first ninth threshold value;
a second deflection signal indicative of a lateral deflection of the probe exceeding a tenth threshold value;
a sum signal indicative of a combined deflection of the probe exceeding an eleventh threshold value; and/or
a driving speed in the z-direction exceeding a twelfth threshold value and/or lying below a thirteenth threshold value.

8. The method according to claim 2, wherein the second set of stop conditions further comprises:
a first deflection signal indicative of a deflection of the probe in the z-direction exceeding a first ninth threshold value;
a second deflection signal indicative of a lateral deflection of the probe exceeding a tenth threshold value;
a sum signal indicative of a combined deflection of the probe exceeding an eleventh threshold value; and/or
a driving speed in the z-direction exceeding a twelfth threshold value and/or lying below a thirteenth threshold value, and
wherein landing the probe is aborted in the second approach phase when at least one of the following conditions are met:
the driving speed exceeds the twelfth threshold value and/or lies below the thirteenth threshold value.

9. The method according to claim 1, further comprising:
capturing a first image of a surface of the sample, the first image comprising a least one section not obscured by the tip;
generating a second image, the second image comprising as least one section obscured by the tip and at least one mark arranged in the obscured section, indicating a position of at least one hidden element; and
displaying the second image on a user interface to an operator of the nanomanipulator during manipulation of the sample.

10. The method according to claim 9, wherein the at least one mark comprises at least one of the following:
a contact point indicator indicating a position of a contact point of the tip with the sample;
a structure indicator indicating an edge or an area of a surface feature or a particle located on the surface of the sample; and
a tip indicator indicating an outline of the tip, wherein the tip is replaced in the second image by a corresponding section of the surface of the sample obtained from the first image.

11. An apparatus, comprising:
a sample stage for holding a sample;
a nanomanipulator comprising a positioning unit and an excitation unit, the positioning unit being configured to move a probe comprising a cantilever and a tip attached thereto, the excitation unit being configured to oscillate the probe based on a driving signal;
a cantilever deflection detection system configured for detecting deflections of the cantilever;
a control loop circuitry configured to track a signal relationship between an oscillation of the cantilever detected by the cantilever detection system and a driving signal provided to the excitation unit; and
at least one control unit configured to perform the following steps:
driving, using the excitation unit, the probe using a resonant driving signal provided by the control loop circuitry while the tip is not in contact with the sample;
reducing, by the positioning unit, a first distance in a z-direction between the tip and the sample during a first approach phase until at least one first stop condition of a first set of stop conditions is met, wherein the first set of stop conditions comprises detecting a shift in the frequency of the resonant driving signal used during the first approach phase; and
terminating the first approach phase when the at least one first stop condition of the first set of stop conditions is met by deactivating the resonant driving signal.

12. The apparatus of claim 11, wherein the control loop circuitry comprises:
a frequency control system configured to provide a first output signal based on a phase of a detected oscillation of the cantilever and a phase setpoint;
an amplitude control system configured to provide a second output signal based on an amplitude of the detected oscillation of the cantilever and an amplitude setpoint; and
a multiplier configured to multiply the first output signal provided by the frequency control system with the second output signal provided by the amplitude control system and to provide the multiplied signal as resonant driving signal to the excitation unit.

13. The apparatus of claim 12, wherein the frequency control system comprises a phase detector for providing a phase signal, an integrator for providing a frequency control signal, and a controllable oscillator for providing an oscillator output signal.

14. The apparatus of claim 12, wherein the amplitude control system comprises an amplitude detector for providing an amplitude signal, and a PI controller for providing an amplitude feedback signal.

15. A computer program product, comprising instructions which, upon execution of the program by at least one computer, cause the computer to carry out the method according to claim 1.

16. A computer-implemented method for processing a sample using a nanomanipulator comprising a measuring tip for processing the sample and a positioning unit for moving the measuring tip, wherein the sample is arranged on a sample stage, and an x-direction and a y-direction of the nanomanipulator are each arranged parallel to a main extension plane of the sample and/or sample stage and perpendicular to one another, the method including the following steps:
1a) controlling the positioning unit to move the measuring tip in the y-direction such that an apex of the measuring tip is in contact with a surface of a test region of the sample stage or sample, and the measuring tip leaves a first track on the surface,
1b) controlling the positioning unit to move the measuring tip in the x-direction such that the apex of the measuring tip is in contact with the surface, and the measuring tip leaves a second track on the surface,
1c) controlling an image recording device to record at least one image of the test region in each case, the first and the second track being at least partially captured accordingly therein, and
1d) ascertaining an x-position of the apex of the measuring tip in relation to the x-direction on the basis of the first track captured in the at least one image and ascertaining a y-position of the apex of the measuring tip in relation to the y-direction on the basis of the second track captured in the at least one image.

17. The method according to claim 16, wherein the nanomanipulator comprises a cantilever having a base end and a free end; the measuring tip is arranged on the free end of the cantilever; at its base end, the cantilever is secured to the positioning unit so as to be movable; and the positioning unit is controlled to move the base end of the cantilever such that the measuring tip is moved.

18. The method according to claim 16, wherein the x-position and the y-position of the apex of the measuring tip are ascertained by accordingly fitting a respective straight line to the first and the second track captured in the image.

19. The method according to claim 16, wherein the measuring tip is at least partially captured in the at least one image, a lateral position of an apparent apex of the measuring tip in the at least one image deviates from a lateral position of an actual apex of the measuring tip in the at least one image and the lateral position of the actual apex of the measuring tip is ascertained relative to the lateral position of the apparent apex of the measuring tip in the at least one image.

20.-28. (canceled)

29. An apparatus for processing a sample, comprising:
a nanomanipulator having a measuring tip for processing the sample and a positioning unit for moving the measuring tip,
a sample stage for arrangement of the sample, wherein an x-direction and a y-direction of the nanomanipulator are each arranged parallel to a main extension plane of the sample and/or sample stage and perpendicular to one another, and
a control apparatus configured to carry out the method according to claim 16.
